(19) United States
(12) Patent Application Publication
(10) Pub. No.: US 2016/0195660 A1
(43) Pub. Date: Jul. 7, 2016

(54) OPTICAL FILM, POLARIZING PLATE, IMAGE DISPLAY DEVICE, AND OPTICAL-FILM MANUFACTURING METHOD

(71) Applicant: FUJIFILM Corporation, Tokyo (JP)

(72) Inventor: Masato NAKAO, Kanagawa (JP)

(73) Assignee: FUJIFILM Corporation, Tokyo (JP)

(21) Appl. No.: 14/987,029

(22) Filed: Jan. 4, 2016

Related U.S. Application Data
(63) Continuation of application No. PCT/JP2014/067001, filed on Jun. 26, 2014.

(30) Foreign Application Priority Data
Jul. 8, 2013 (JP) 2013-142782
May 23, 2014 (JP) 2014-107006

(51) Int. Cl. G02B 5/30; H01L 51/52; G02F 1/13363; G02B 7/00; G02B 1/14

(52) U.S. Cl. CPC G02B 5/3083; G02B 7/003; G02B 1/14; G02F 1/13363; H01L 51/5281

(57) ABSTRACT

Objects of the present invention are to provide a wrinkle-free optical film which is excellent in the adhesiveness between a support and an alignment film and to provide a polarizing plate and an image display device which use the optical film. The optical film of the present invention has a transparent support, an alignment film, and an optically anisotropic layer in this order, in which the transparent support contains an acrylic resin, and a mixed layer, which has a thickness of 50 nm to 200 nm and in which a material constituting the transparent support is mixed with a material constituting the alignment film, is between the transparent support and the alignment film.

### CROSS-REFERENCE TO RELATED APPLICATIONS

This application is a Continuation of PCT International Application No. PCT/JP2014/067001 filed on Jun. 26, 2014, which claims priority under 35 U.S.C. §119(a) to Japanese Patent Application No. 2013-142782 filed on Jul. 8, 2013 and Japanese Patent Application No. 2014-107006 filed on May 23, 2014. Each of the above applications is hereby expressly incorporated by reference, in its entirety, into the present application.

### BACKGROUND OF THE INVENTION

1. Field of the Invention

The present invention relates to an optical film, a polarizing plate, an image display device, and an optical-film manufacturing method.

2. Description of the Related Art

A phase difference plate composed of an optically anisotropic material is used in display devices such as an LCD display device, an organic EL display device, a touch panel, and a brightness enhancement film.

In such a phase difference plate, a cellulose resin-based film (particularly, a cellulose acylate (TAC) film) is generally used as a support (for example, see JP2008-217001A and JP2012-008170A).

The cellulose acylate (TAC) film is known to undergo a great dimensional change depending on the temperature or humidity (for example, see JP2011-191756A). The TAC film causes an alignment film to expand or contract according to the dimensional change of the support, which leads to the change in retardation in the plane (particularly, the end) of an optically anisotropic layer.

### SUMMARY OF THE INVENTION

The inventor of the present invention examined an acrylic resin, which undergoes a slight dimensional change depending on the temperature or humidity, as a material of a support. As a result, it was revealed that depending on a solvent used in a coating solution for forming an alignment film provided on the support, the obtained optical film is wrinkled, or the adhesiveness between the support and the alignment film deteriorates in some cases.

Therefore, objects of the present invention are to provide a wrinkle-free optical film which is excellent in the adhesiveness between a support and an alignment film, and to provide a polarizing plate and an image display device which use the optical film.

In order to achieve the aforementioned objects, the inventor of the present invention conducted intensive examination. As a result, the inventor obtained knowledge that by forming a mixed layer, in which a material constituting a transparent support is mixed with a material constituting an alignment film and which has a specific thickness, between the support and the alignment film, it is possible to prepare a wrinkle-free optical film which is excellent in the adhesiveness between the support and the alignment film. Based on the knowledge, the inventor accomplished the present invention.

That is, the inventor obtained knowledge that the aforementioned objects can be achieved by the following constitutions.

[1] An optical film including a transparent support, an alignment film, and an optically anisotropic layer in this order, in which the transparent support contains an acrylic resin, and a mixed layer, which has a thickness of 50 nm to 200 nm and in which a material constituting the transparent support is mixed with a material constituting the alignment film, is between the transparent support and the alignment film.

[2] The optical film described in [1], in which in-plane retardation of the optically anisotropic layer is 40 nm to 240 nm at a wavelength of 550 nm

[3] The optical film described in [1] or [2], in which the alignment film contains a polyvinyl alcohol derivative.

[4] The optical film described in any one of [1] to [3], in which the optically anisotropic layer is a patterned optically anisotropic layer having two or more phase difference regions which differ from each other in terms of at least one of the in-plane slow axis direction and the in-plane retardation.

[5] The optical film described in any one of [1] to [4], further including a hardcoat layer.

[6] A polarizing plate including the optical film described in any one of [1] to [5] and a polarizer.

[7] An image display device including the optical film described in any one of [1] to [5], a polarizer, and a liquid crystal cell or an organic EL display panel.

[8] The image display device described in [7] including the optical film, the polarizer, and the liquid crystal cell in this order from a viewing side.

[9] The image display device described in [7] including the polarizer, the optical film, and the liquid crystal cell in this order from a viewing side.

[10] The image display device described in [7] including the polarizer, the optical film, and the organic EL display panel in this order from a viewing side.

[11] An optical-film manufacturing method for preparing the optical film described in any one of [1] to [5], including a mixed layer•alignment film-forming step of forming an alignment film on a transparent support containing an acrylic resin by using a coating solution, which contains one kind of solvent or two or more kinds of solvents and in which the solvent has an average SP value of 25 to 55, and forming a mixed layer, which has a thickness of 50 nm to 200 nm and in which a material constituting the transparent support is mixed with a material constituting the alignment film, between the transparent support and the alignment film, and an optically anisotropic layer-forming step of forming an optically anisotropic layer on the alignment film by using a composition for forming an optically anisotropic layer containing a liquid crystal compound so as to prepare an optical film.

[12] The optical-film manufacturing method described in [11], in which the average SP value of the solvent is 25 to 40.

[13] The optical-film manufacturing method described in [11] or [12], in which the concentration of solid contents in the coating solution is equal to or less than 60% by mass.

According to the present invention, it is possible to provide a wrinkle-free optical film which is excellent in the adhesiveness between a support and an alignment film, and to provide a polarizing plate and an image display device which use the optical film.

### BRIEF DESCRIPTION OF THE DRAWINGS

Each of FIG. 1(A) to 1(C) is a schematic cross-sectional view showing an example of an optical film of the present invention.

Each of FIGS. 2(A) and 2(B) is a schematic cross-sectional view showing an example of a polarizing plate of the present invention.

Each of FIG. 3(A) to 3(D) is a schematic cross-sectional view showing an example of an image display device (liquid crystal display device) of the present invention.

Each of FIGS. 4(A) and 4(B) is a schematic cross-sectional view showing an example of the image display device (organic EL display device) of the present invention.

FIG. 5 is a picture of a cross-section of a laminate composed of a transparent support, a mixed layer, and an alignment film, captured by a scanning electron microscope (SEM) at a 50,000× magnification.

Each of FIG. 6(A) to 6(C) is a schematic front view showing an example of a patterned optically anisotropic layer.

FIG. 7 is a schematic view showing an example of the polarizing plate (patterned circularly polarizing plate) of the present invention.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

In the present specification, a range of numerical values described by using “to” means a range which includes numerical values listed before and after “to” as a lower limit and an upper limit.

Next, the terms used in the present specification will be described.

[Retardation (Re)]

Re(λ) and Rth(λ) represent the in-plane retardation at a wavelength λ and the retardation in a thickness direction, respectively. Re(λ) is measured by applying light having a wavelength of λ nm to a film in the normal direction of the film, in KOBRA 21ADH or KOBRA WR (both manufactured by Oji Scientific Instruments). A measurement wavelength λ nm can be selected by manually replacing a wavelength selective filter, or, the measured value can be converted by using a program or the like during the measurement. The method for measuring Re(λ) and Rth(λ) is described in detail in paragraphs “0010” to “0012” of JP2013-041213A, the content of which is incorporated in the present specification by reference.

In the present specification, in a case in which there is no particular description regarding the measurement wavelength, the measurement wavelength is 550 nm

Furthermore, in the present specification, an angle (for example, an angle of “90°”) and an angular relationship (for example, “orthogonal”, “parallel”, “the same direction”, and “crossing at 45°”) include the margin of allowable error in the field of the related art to which the present invention belongs. At this time, the allowable error means that the margin of the error is less than a precise angle ±10°. Specifically, a difference between an actual angle and the precise angle is preferably equal to or less than 5°, and more preferably equal to or less than 3°.

1. Optical Film

The present invention relates to an optical film having a transparent support, an alignment film, and an optically anisotropic layer in this order.

In the optical film of the present invention, the transparent support contains an acrylic resin, and a mixed layer, in which a material constituting the transparent support is mixed with a material constituting the alignment film, between the transparent support and the alignment film.

As described above, the inventor of the present invention obtained knowledge that by forming the mixed layer, in which the material constituting the transparent support is mixed with the material constituting the alignment film, between the support and the alignment film at a specific thickness, it is possible to prepare a wrinkle-free optical film which is excellent in the adhesion between the support and the alignment film.

The inventor of the present invention assumes that such an effect may be obtained for the following reasons.

First, the inventor found that when the average SP value of a solvent contained in a coating solution for forming an alignment film is less than 25, the transparent support containing an acrylic resin dissolves at the time of forming the alignment film, the support contracts at the time of drying the coating solution, and thus the optical film is wrinkled (see Comparative examples 4 and 5).

The inventor also found that, in contrast, when the average SP value of the solvent contained in the coating solution for forming an alignment film is greater than 55, the transparent support does not dissolve at all, and accordingly, the interfacial adhesion between the transparent support and the alignment film weakens, and the alignment film is peeled off (see Comparative examples 1 to 3).

It is considered that, in the present invention, because the alignment film is formed by using a coating solution containing a solvent having an average SP value of 25 to 55, the surface of the transparent support dissolves slightly. Furthermore, it is considered that, in the present invention, because the mixed layer in which the transparent support (acrylic resin) is mixed with the alignment film is formed at an intended thickness, the occurrence of wrinkles is inhibited, and the adhesiveness becomes excellent.

FIGS. 1(A)-1(C) are schematic cross-sectional views showing an example of the optical film of the present invention.

Herein, the drawing in the present invention is a schematic view, so the relationship of the thickness between the respective layers or the positional relationship between the respective layers in the drawing does not necessarily agree with the actual ones. The same is true for the following drawings.

An optical film 10 shown in FIGS. 1(A)-1(C) has a transparent support 16, a mixed layer 15, an alignment film 14, and an optically anisotropic layer 12 in this order.

Furthermore, as shown in FIG. 1(B), the optical film 10 may have a hardcoat layer 18 on a side of the transparent support 16 opposite to a side provided with the mixed layer 15. Alternatively, as shown in FIG. 1(C), the optical film 10 may have the hardcoat layer 18 on a side of the optically anisotropic layer 12 opposite to a side provided with the alignment film 14.

2. Polarizing Plate

The present invention also relates to a polarizing plate using the optical film of the present invention (hereinafter, also simply referred to as a “polarizing plate of the present invention”).

The polarizing plate of the present invention has the optical film of the present invention and a polarizer.

FIGS. 2(A) and 2(B) are schematic cross-sectional views showing an example of the polarizing plate of the present invention.

A polarizing plate 20 shown in FIG. 2(A) has the optically anisotropic layer 12, the alignment film 14, the mixed layer 15, the transparent support 16, and a polarizer 22 in this order.

Furthermore, the polarizing plate 20 shown in FIG. 2(B) has the transparent support 16, the mixed layer 15, the alignment film 14, the optically anisotropic layer 12, and the polarizer 22 in this order.

In addition, a polarizer protective film 24 may be optionally disposed on a surface of the polarizer 22 opposite to the other surface thereof on which the optical film 10 is disposed. Likewise, if necessary, a polarizer protective film not shown in the drawing may be disposed on a surface of the polarizer 22 on which the optical film 10 is disposed.

Herein, the optically anisotropic layer 12, the alignment film 14, the mixed layer 15, and the transparent support 16 in the polarizing plate 20 are constituted with the optical film 10 shown in FIG. 1(A) described above. However, they may be constituted as in the embodiments shown in FIGS. 1(B) and 1(C). Specifically, in the embodiment shown in FIG. 2(A), the hardcoat layer 18 may be provided on the optically anisotropic layer 12, and in the embodiment shown in FIG. 2(B), the hardcoat layer 18 may be provided on the transparent support 16.

The transparent support 16 and the polarizer 22 in FIG. 2(A) and the optically anisotropic layer 12 and the polarizer 22 in FIG. 2(B) may be bonded to each other through a pressure-sensitive adhesive or an adhesive not shown in the drawings.

3. Image Display Device

The present invention also relates to an image display device using the optical film of the present invention (hereinafter, also simply referred to as an “image display device of the present invention”).

The image display device of the present invention has the optical film of the present invention, a polarizer, and a liquid crystal cell or an organic EL display panel.

FIGS. 3(A)-3(D) are schematic cross-sectional views showing a liquid crystal display device which is an example of the image display device of the present invention.

In a liquid crystal display device 30 shown in FIGS. 3(A) and 3(B), the polarizing plate 20 of the present invention is disposed such that the optical film 10 of the present invention becomes the uppermost surface (viewing side).

In contrast, in the liquid crystal display device 30 shown in FIGS. 3(C) and 3(D), the polarizing plate 20 of the present invention is disposed such that a protective film 24 for the polarizer 22 on the viewing side becomes the uppermost surface (viewing side).

On the front and rear surfaces of a polarizer 34 on a backlight side, polarizer protective films 36 and 38 are optionally disposed, respectively. Herein, as the polarizer protective films 36 and 38, an optical compensation film compatible with the driving mode of the liquid crystal cell may be used.

Herein, the respective layers may be bonded to each other through a pressure-sensitive adhesive or an adhesive not shown in the drawings.

FIGS. 4(A) and 4(B) are schematic cross-sectional views showing an organic electroluminescence (EL) display device which is an example of the image display device of the present invention.

An organic EL display device 40 shown in FIGS. 4(A) and 4(B) has the polarizing plate 20 of the present invention, which is disposed such that the protective film 24 for the polarizer 22 becomes the upper most surface (viewing side), and an organic EL display panel 42.

Herein, the respective layers may be bonded to each other through a pressure-sensitive adhesive or an adhesive not shown in the drawings.

[Optical Film]

Hereinafter, various members used in the optical film of the present invention will be specifically described.

[Transparent Support]

The transparent support in the optical film of the present invention contains at least an acrylic resin.

The “acrylic resin” refers to a polymer of an acrylic acid ester or a methacrylic acid ester. In the following description, the resin is also referred to as a “(meth)acrylic polymer”. Herein, conceptually, the (meth)acrylic polymer includes both the methacrylic polymer and the acrylic polymer.

The content of the acrylic resin in the transparent support is not particularly limited, but the acrylic resin is preferably a main component of the transparent support (the content of the acrylic resin is preferably greater than 50% by mass of the solid contents of the transparent support). More preferably, the content of the acrylic resin is 70% by mass to 97% by mass of the solid contents of the transparent support.

In the present invention, as the acrylic resin, it is possible to appropriately use the acrylic resin or the copolymerization component described in paragraphs “0033” to “0063” of JP2010-079175A.

As the acrylic resin, commercially available products can be used. For example, it is possible to use PMMA (Dianal BR88, weight average molecular weight: 1,500,000, manufactured by Mitsubishi Rayon Co., Ltd.), Arton (F5023, manufactured by JSR Corporation), and the like.

[Mixed Layer]

The mixed layer in the optical film of the present invention is a layer in which a material (acrylic resin) constituting the aforementioned transparent support is mixed with a material constituting the alignment film which will be described later.

Herein, the presence and thickness of the mixed layer can be confirmed by the following procedure.

First, by using an ultramicrotome EM UC6 manufactured by Leica Microsystems and a diamond knife manufactured by DiATOME, a laminate in which the alignment film, which will be described layer, has been formed on the transparent support is cut in the thickness direction thereof.

Thereafter, a hydrophilization treatment is performed on the cut surface by using a hydrophilization device HDT-400 manufactured by JEOL Datum Ltd.

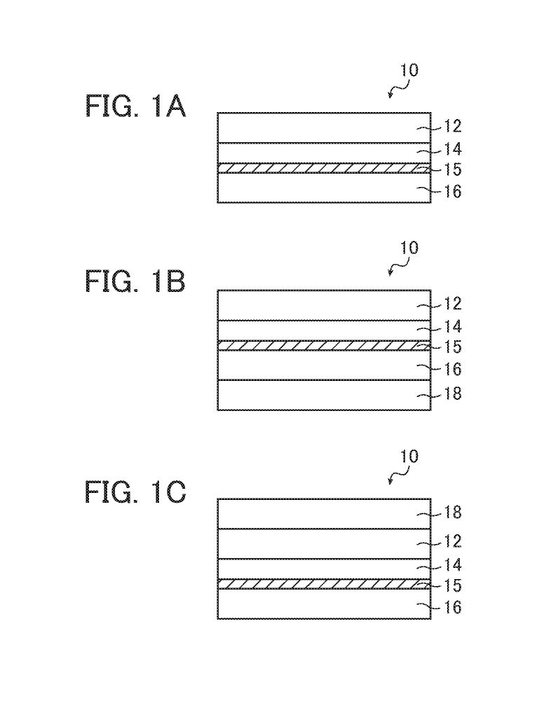

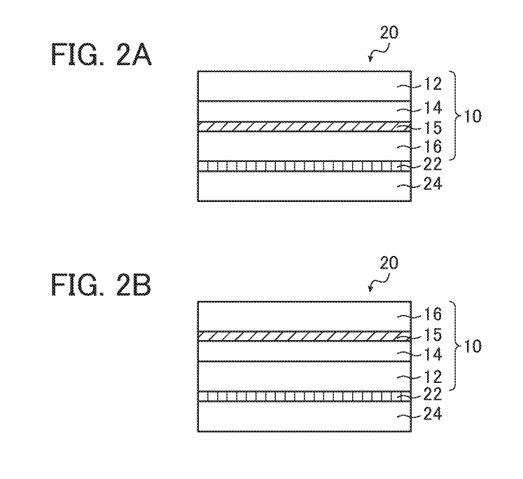

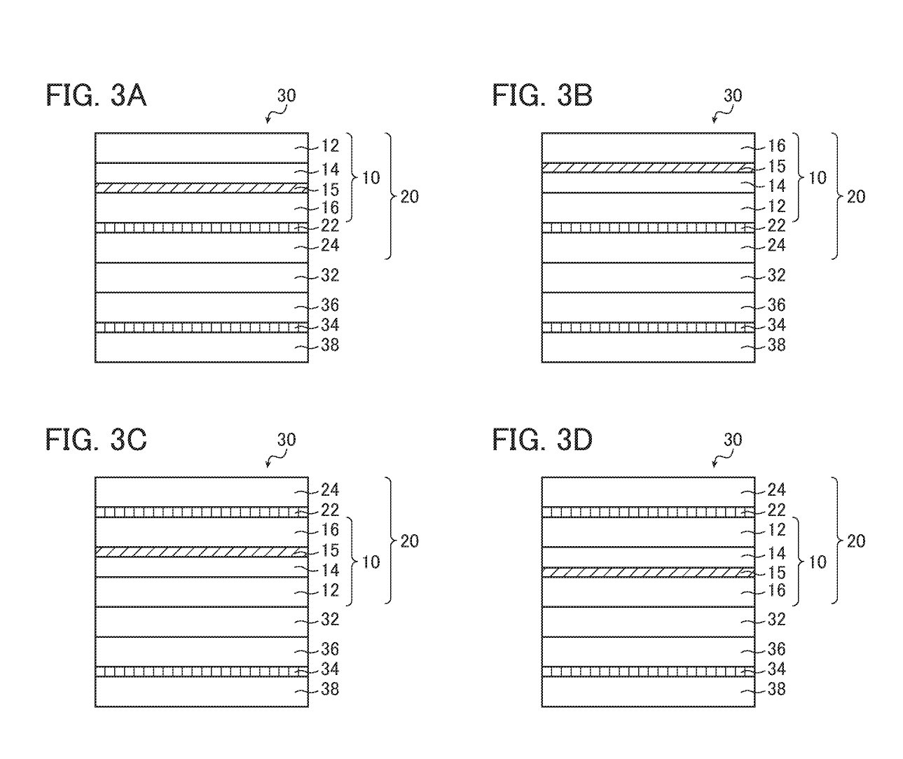

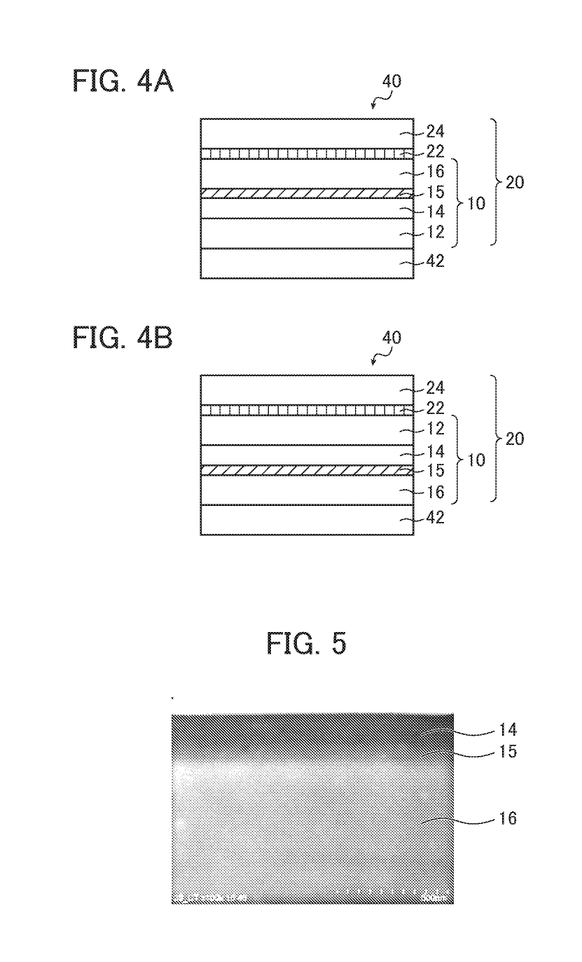

Subsequently, the cut surface having undergone the hydrophilization treatment is coated with osmium by using a Neo Osmium Coater manufactured by MEIWAFOSIS CO., LTD, and then observed with a scanning electron microscope (SEM) S-5500 model manufactured by Hitachi High-Technologies Co., Ltd. at a 50,000× magnification. In this way, the presence and thickness of the mixed layer can be checked (see FIG. 5).

In the present invention, the thickness of the mixed layer is 50 nm to 200 nm Because the adhesiveness between the support and the alignment film is further improved, and the linearity of a stripe-like pattern of the patterned optically anisotropic layer becomes excellent when the optical film of the present invention is used in a stereoscopic image display device, the thickness of the mixed layer is preferably 80 nm to 150 nm

Furthermore, in the present invention, a ratio of the material (acrylic resin) constituting the transparent support described above to the material constituting the alignment film, which will be described later, in the mixed layer is preferably 1/99 to 99/1, and more preferably 10/90 to 90/10.

[Alignment Film]

The alignment film in the optical film of the present invention is provided between the transparent support and the optically anisotropic layer and is for forming the optically anisotropic layer.

As described above, the alignment film contains one kind of solvent or two or more kinds of solvents, and is formed by using a coating solution containing a solvent having an average SP value of 25 to 55.

Herein, the SP value is a parameter of a degree of solubility calculated by a Hoy method [Low-molecular Liquid (Solvents)].

The average SP value refers to the average of the SP value of each solvent corresponding to the mass ratio thereof. Specifically, the average SP value can be calculated by using the following Equation (I). Herein, when only a single kind of solvent is used, the average SP value refers to the SP value of the solvent.

$$Average SP value = {\sum }_{i = 1}^{n} ( Si \times Wi ) \qquad Equation ( I )$$

(In the equation, Σ represents the sum; Si represents an SP value of an i-th solvent; and Wi represents a mass ratio of the i-th solvent to all solvents (mass of the i-th solvent/total mass of all solvents).

Herein, the solvent having an SP value of 25 to 55 is preferably an alcohol-based solvent, and specific examples thereof include methanol [Sp value: 37], ethanol [SP value: 31], n-propyl alcohol [SP value: 28], isopropyl alcohol (hereinafter, also abbreviated to “IPA”) [SP value: 27], n-butyl alcohol (hereinafter, also abbreviated to “n-BuOH”) [SP value: 26], isobutyl alcohol (hereinafter, also abbreviated to “i-BuOH”) [SP value: 25], propylene glycol (hereinafter, abbreviated to “PG”) [SP value: 32], and the like. One kind of these may be used singly, or two or more kinds thereof may be used concurrently.

In the present invention, when two or more kinds of solvents are used by being mixed together, as long as the solvent mixture has an SP value of 25 to 55, other solvents having an SP value not satisfying 25 to 55 may be used concurrently.

Other solvents described above are not particularly limited, and examples thereof include water [SP value: 72], 2-butanol [SP value: 24], tert-butyl alcohol [SP value: 22], acetone [SP value: 24], methyl ethyl ketone (hereinafter, also abbreviated to “MEK”) [SP value: 22], and the like.

When other solvents described above are used, from the viewpoint of compatibility, a difference in the SP value between the respective solvents is preferably equal to or less than 50.

In the present invention, because the adhesiveness is further improved, the average SP value of the solvents (including the solvent mixture) described above is preferably 25 to 40.

The alignment film generally contains a polymer as a main component. The polymer material of the alignment film is described in many documents, and a large number of commercial polymer materials are available. As the polymer material used in the present invention, polyvinyl alcohol, polyimide, and derivatives of these are preferable. Particularly, modified or unmodified polyvinyl alcohol is preferable. Regarding the alignment film which can be used in the present invention, the modified polyvinyl alcohol described on p. 43, line 24 to p. 49, line 8 of WO01/88574A1 and in paragraphs “0071” to “0095” of JP3907735B can be referred to.

From the viewpoint of oxygen permeability, it is preferable that the alignment film has a small thickness. However, from the viewpoint of imparting an alignment ability for forming an optically anisotropic layer and from the viewpoint of forming an optically anisotropic layer having a uniform film thickness by mitigating the irregularity of the support surface, the alignment film needs to have a certain thickness. Specifically, the thickness of the alignment film is preferably 0.01 μm to 10 μm, more preferably 0.01 μm to 1 μm, and even more preferably 0.01 μm to 0.5 μm.

In the present invention, it is preferable to use an optical alignment film. The optical alignment film is not particularly limited, and it is possible to use a polymer material such as a polyamide compound or a polyimide compound described in paragraphs “0024” to “0043” of WO2005/096041A, LPP-JP265CP (trade name) manufactured by Rolic technologies, and the like.

[Optically Anisotropic Layer]

The optically anisotropic layer in the optical film of the present invention contains a liquid crystal compound.

<Liquid Crystal Compound>

Generally, the liquid crystal compound can be classified into a rod type and a disk type based on the shape thereof. Furthermore, each of the rod type and the disk type includes a low-molecular weight type and a polymer type. Generally, a polymer refers to a molecule having a degree of polymerization of equal to or greater than 100 (“Polymer Physics•Dynamics of Phase Transition”, Masao Doi, p. 2, Iwanami Shoten, Publishers., 1992). In the present invention, any of the liquid crystal compounds can be used, but it is preferable to use a rod-like liquid crystal compound and a discotic liquid crystal compound (disk-like liquid crystal compound). Furthermore, two or more kinds of rod-like liquid crystal compounds, two or more kinds of disk-like liquid crystal compounds, or a mixture of a rod-like liquid crystal compound and a disk-like liquid crystal compound may be used. In order to fix the aforementioned liquid crystal compound, the optically anisotropic layer is more preferably formed by using a rod-like liquid crystal compound or a disk-like liquid crystal compound having a polymerizable group. Even more preferably, the liquid crystal compound has two or more polymerizable groups in a single molecule. When the liquid crystal compound is a mixture of two or more kinds thereof, it is preferable that at least one kind of liquid crystal compound has two or more polymerizable groups in a single molecule.

As the rod-like liquid crystal compound, for example, it is possible to preferably use those described in claim 1 of JP1999-513019A (JP-H11-513019A) or in paragraphs “0026” to “0098” of JP2005-289980A. As the discotic liquid crystal compound, for example, it is possible to preferably use those described in paragraphs “0020” to “0067” of JP2007-108732A or in paragraphs “0013” to “0108” of JP2010-244038A. However, the present invention is not limited thereto.

<Alignment>

The molecules of the liquid crystal compound are preferably fixed in any of the alignment states including vertical alignment, horizontal alignment, hybrid alignment, and tilt alignment.

The hybrid alignment is an alignment state in which the angle between the plane of the disk of the disk-like liquid crystal compound molecule or the molecule symmetry axis of the rod-like liquid crystal compound molecule and the plane of the layer increases or decreases in the depth direction of the optically anisotropic layer as the distance from the surface of the alignment film increases.

The aforementioned angle preferably increases as the distance increases.

Furthermore, the mode of change of the angle includes continuous increase, continuous decrease, intermittent increase, intermittent decrease, and a combination of continuous increase and continuous decrease. Alternatively, the mode of change can also be intermittent change including increase and decrease. The mode of intermittent change includes a region in which the tilt angle does not change in the middle of the thickness direction.

The aforementioned angle may not change in a certain region as long as the angle increases or decreases as a whole. However, the angle preferably changes continuously. Needless to say, an alignment state may also be adopted in which all the liquid crystal compound molecules are uniformly tilted.

As the embodiment in which the liquid crystal compound is fixed in the hybrid alignment state as described above, an embodiment is exemplified in which the optically anisotropic layer is used as an optical compensation film of a liquid crystal display device adopting a twisted alignment mode. Specifically, those described in paragraphs “0123” to “0126” of JP2012-3183A can be used, but the present invention is not limited thereto.

In some cases, in order to make the optically anisotropic layer function as aλ/4 plate, the alignment state of the liquid crystal compound is controlled.

Theλ/4 plate (plate having aλ/4 function) is a plate having a function of converting linearly polarized light at a specific wavelength into circularly polarized light (or converting circularly polarized light into linearly polarized light). More specifically, it is a plate in which a value of in-plane retardation at a predetermined wavelength λ nm becomesλ/4 (or an odd multiple thereof).

When the λ/4 plate has a single-layer structure, an angle formed between the absorption axis of a polarizer and the in-plane slow axis of the λ/4 plate is preferably 45°. When the λ/4 plate has a structure composed of a plurality of layers laminated on each other, it is possible to appropriately adopt a known constitution•axial relationship.

As the embodiment in which the 214 plate has a single-layer structure, a stretched polymer film, a phase difference film in which an optically anisotropic layer having the λ/4 function is provided on a support, and the like are exemplified.

Furthermore, as the embodiment in which the λ/4 plate has a multilayer structure, a broadbandλ/4 plate composed of aλ/4 plate and a λ/2 plate laminated on each other is exemplified. In the broadbandλ/4 plate, an angle formed between the in-plane slow axis of the λ/4 plate and the in-plane slow axis of the λ/2 plate is preferably 60°.

The material constituting the λ/4 plate is not particularly limited as long as it exhibits the characteristics described above. As the material, an embodiment in which the λ/4 plate contains a liquid crystal compound as described above for the aforementioned optically anisotropic layer (for example, an optically anisotropic layer containing a homogeneously aligned liquid crystal compound), a polymer film, and the like are exemplified. Particularly, from the viewpoint of easily controlling the aforementioned characteristics, the λ/4 plate preferably contains a liquid crystal compound. More specifically, the λ/4 plate is preferably a layer formed by fixing a liquid crystal compound (a rod-like liquid crystal compound or a discotic liquid crystal compound) having a polymerizable group by means of polymerization or the like. In this case, after being formed into a layer, the liquid crystal compound does not need to exhibit liquid crystallinity.

At this time, when a rod-like liquid crystal compound is used, the rod-like liquid crystal compound is preferably fixed in a horizontal alignment state. Furthermore, when a discotic liquid crystal compound is used, the discotic liquid crystal compound is preferably fixed in a vertical alignment state. Herein, in the present invention, the phrase “the rod-like liquid crystal compound is in a horizontal alignment state” means that a director of the rod-like liquid crystal compound is parallel to the plane of the layer. In addition, the phrase “the discotic liquid crystal compound is in a vertical alignment state” means that the plane of the disk of the discotic liquid crystal compound is perpendicular to the plane of the layer. However, the phrases do not mean that the liquid crystal compound needs to be precisely horizontally or vertically aligned, but means that there may be a difference within a range of ±20° from the precise angle. The difference is preferably within ±5°, more preferably within ±3°, even more preferably within ±2°, and most preferably within ±1°.

In order to put the liquid crystal compound in the horizontal alignment state or the vertical alignment state, an additive (alignment control agent) accelerating the horizontal alignment or the vertical alignment may be used. Various known components can be used as the additive.

The method for forming the λ/4 plate is not particularly limited, and a known method can be adopted. For example, a method for forming a first optically anisotropic layer described above (method of using a composition containing a liquid crystal compound having a polymerizable group) can be adopted.

<Retardation>

The retardation of the optical film of the present invention is not particularly limited because the retardation varies with the use of the image display device to be used. However, the in-plane retardation at a wavelength of 550 nm is preferably 40 nm to 240 nm

Particularly, because light can become approximate to accurate circularly polarized light, the optically anisotropic layer preferably has a phase difference region where the phase difference is about λ/4 in the image display device. Specifically, there may be a difference of about 25 nm between the value of in-plane retardation (Re(550)) at a wavelength of 550 nm and an ideal value (137.5 nm). For example, the value of in-plane retardation is more preferably 110 nm to 165 nm, even more preferably 115 nm to 150 nm, and particularly preferably 120 nm to 145 nm.

When the optical film of the present invention is caused to function as aλ/4 plate having a multilayer structure, for example, a broadbandλ/4 plate composed of aλ/4 plate and a λ/2 plate laminated on each other as described above, there may be a difference of about 25 nm between the value of in-plane retardation (Re(550)) at a wavelength of 550 nm of the optically anisotropic layer corresponding to the λ/2 plate and an ideal value (275 nm). For example, the value of in-plane retardation is preferably 250 nm to 300 nm, and more preferably 260 nm to 290 nm.

In contrast, when the optical film of the present invention is used as an optical compensation film of a TN-mode liquid crystal cell, the in-plane retardation at a wavelength of 550 nm is preferably 40 nm to 80 nm.

<Thickness>

In the present invention, the thickness of the optically anisotropic layer is not particularly limited, but is preferably 0.1 μm to 10 μm and more preferably 0.5 μm to 5 μm.

<Patterned Optically Anisotropic Layer>

In the present invention, the optically anisotropic layer is preferably a patterned optically anisotropic layer having two or more phase difference regions which differ from each other in terms of at least one of the in-plane slow axis direction and the in-plane retardation, because such an optically anisotropic layer can create right-hand circularly polarized light and left-hand circularly polarized light and can be preferably used in a stereoscopic image display device. Specifically, the optically anisotropic layer is more preferably a patterned optically anisotropic layer which has a first phase difference region and a second phase difference region differing from each other in terms of at least one of the in-plane slow axis direction and the in-plane retardation and in which the first and second phase difference regions are alternately arranged within the plane.

Each of FIG. 6(A) to 6(C) is a schematic front view showing an example of the patterned optically anisotropic layer.

For example, the optically anisotropic layer 12 shown in FIG. 6(A) to 6(C) is a patterned optically anisotropic layer which has a first phase difference region 12a and a second phase difference region 12b differing from each other in terms of at least one of the in-plane slow axis direction and the in-plane retardation and in which the first phase difference region 12a and the second phase difference region 12b are alternately arranged within the plane. The first phase difference region 12a and the second phase difference region 12b have in-plane slow axes a and b, respectively, that are orthogonal to each other.

Regarding the shape and the arrangement pattern of the first phase difference region 12a and the second phase difference region 12b in the optically anisotropic layer 12, an embodiment may be adopted in which stripe-like patterns are alternately arranged as shown in FIGS. 6(A) and 6(B), or an embodiment may be adopted in which rectangular patterns are arranged in the form of a lattice as shown in FIG. 6(C).

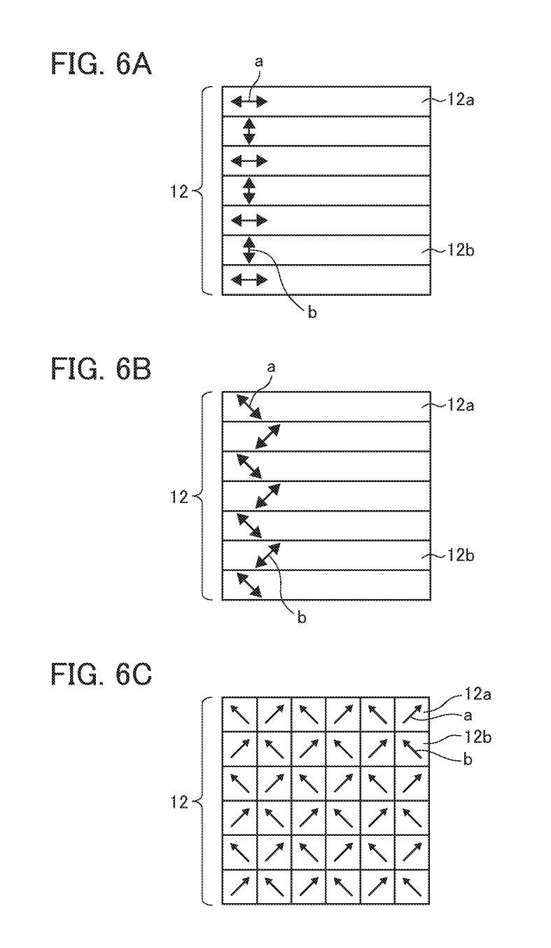

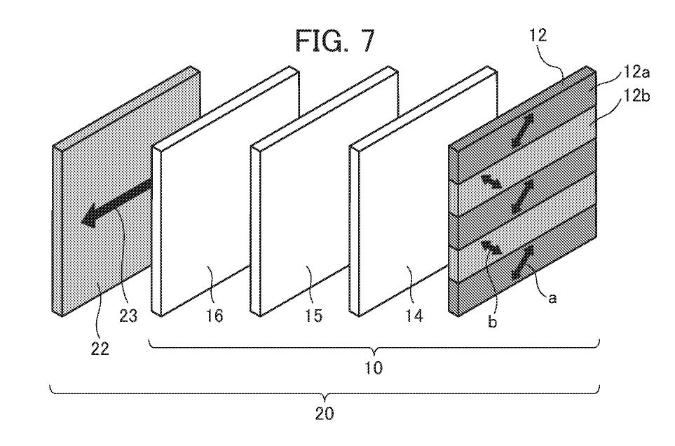

When the polarizing plate, which will be described later, of the present invention is used as a circularly polarizing plate, as shown in FIG. 7, a polarizing plate 20 (circularly polarizing plate) is disposed such that each of the first phase difference region 12a and the second phase difference region 12b in the optically anisotropic layer 12 has a phase difference of aboutλ/4, and that the slow axis a of the first phase difference region 12a, the slow axis b of the second phase difference region 12b, and an absorption axis 23 of the polarizer 22 cross each other at an angle of 45° with respect to the optical film 10 in which there is a difference of 90° between the directions of the slow axes a and b (provided that the slow axes a and b of a first phase difference region 12a and a second phase difference region 12b are at an angle of 45°, the absorption axis 23 of the polarizer 22 is at an angle of 0°.

As the method for forming the aforementioned patterned optically anisotropic layer, the following preferred embodiments are exemplified. However, the present invention in not limited thereto, and the patterned optically anisotropic layer can be formed by using various known methods.

A first preferred embodiment is a method of utilizing a plurality of actions for controlling the alignment of the liquid crystal compound and then canceling one of the actions by using an external stimulus (thermal treatment or the like) such that a predetermined alignment control action becomes predominant In such a method, for example, the liquid crystal compound is caused to be in a predetermined alignment state by the composite action of the alignment control ability resulting from the alignment film and the alignment control ability of the alignment control agent added to the liquid crystal compound, and one of the phase difference regions is formed by fixing the alignment state. Thereafter, one of the actions (for example, the action resulting from the alignment control agent) is canceled by an external stimulus (thermal treatment or the like), such that the other alignment control action (action resulting from the alignment film) becomes predominant. In this way, the other alignment state is realized, and the other phase difference region is formed by fixing the alignment state. Details of this method are described in paragraphs “0017” to “0029” of JP2012-008170A, the content of which is incorporated in the present specification by reference.

A second preferred embodiment is an embodiment in which patterned alignment films are used. In this embodiment, patterned alignment films having different alignment control abilities are formed, and liquid crystal compounds are disposed thereon and aligned. Due to the alignment control abilities of the respective patterned alignment films, the liquid crystal compounds achieve different alignment states, respectively. By fixing the alignment states, patterns of the first and second phase difference regions are formed according to the patterns of the alignment films. The patterned alignment films can be formed by using a printing method, mask rubbing performed on a gravure alignment film, mask exposure performed on a photoalignment film, or the like. It is preferable to use a printing method because this method does not require large-scale facilities and easily produces the patterned alignment films. Details of this method are described in paragraphs “0166” to “0181” of JP2012-032661A, the content of which is incorporated in the present specification by reference.

A third preferred embodiment is an embodiment in which a photoacid generator is added to the alignment film, for example. In this embodiment, a photoacid generator is added to the alignment film, and by pattern exposure, a region in which an acidic compound is generated as a result of decomposition of the photoacid generator and a region in which an acidic compound is not generated are formed. In a portion not irradiated with light, the photoacid generator substantially remains undecomposed, and the interaction between the material of the alignment film, the liquid crystal compound, and the alignment control agent which is added if necessary dominates the alignment state. As a result, the liquid crystal compound is aligned in a direction in which the slow axis thereof becomes orthogonal to the rubbing direction. When the alignment film is irradiated with light, and thus an acidic compound is generated, the aforementioned interaction is no longer predominant As a result, the rubbing direction of the rubbing alignment film dominates the alignment state, and the liquid crystal compound is put in a parallel alignment state in which the slow axis thereof is parallel to the rubbing direction. As the photoacid generator used in the alignment film, a water-soluble compound is preferably used. Examples of the usable photoacid generator include the compounds described in Prog. Polym. Sci., vol. 23, p. 1485 (1998). As the photoacid generator, a pyridinium salt, an iodonium salt, and a sulfonium salt are particularly preferably used. Details of the method are described in JP2010-289360, the content of which is incorporated in the present specification by reference.

[Other Layers and Optional Components]

<Hardcoat Layer>

The optical film of the present invention preferably has a hardcoat layer such that a physical strength is imparted to the film. Specifically, the optical film may have a hardcoat layer on a side of the transparent support opposite to the side provided with the alignment film (see FIG. 1(B)) or on a side of the optically anisotropic layer opposite to the side provided with the alignment film (see FIG. 1(C)).

As the hardcoat layer, it is possible to use those described in paragraphs “0190” to “0196” of JP2009-98658A.

<Ultraviolet Absorber>

Considering the influence of external light (particularly, ultraviolet rays), the optical film of the present invention preferably contains an ultraviolet (UV) absorber and more preferably contains the ultraviolet absorber in the transparent support.

As the ultraviolet absorber, any of known ultraviolet absorbers which can exhibit ultraviolet absorbing properties can be used. Among such ultraviolet absorbers, in order to obtain a high degree of ultraviolet absorbing properties and obtain ultraviolet absorbability (ultraviolet cutting ability) utilized in an electronic image display device, a benzotriazole or hydroxyphenyl triazine-based ultraviolet absorber is preferable. Furthermore, in order to widen the range of ultraviolet rays absorbed, it is possible to concurrently use two or more kinds of ultraviolet absorbers having different maximum absorption wavelengths.

[Optical-Film Manufacturing Method]

The method for preparing the optical film of the present invention is an optical-film manufacturing method including a mixed layer•alignment film-forming step of forming an alignment film on a transparent support containing an acrylic resin by using a coating solution, which contains one kind of solvent or two or more kinds of solvents and in which the solvent has an average SP value of 25 to 55, and forming a mixed layer, in which a material constituting the transparent support is mixed with a material constituting the alignment film, between the transparent support and the alignment film, and an optically anisotropic layer-forming step of forming an optically anisotropic layer on the alignment film by using a composition for forming an optically anisotropic layer containing a liquid crystal compound so as to prepare an optical film.

Herein, the transparent support, the coating solution for forming the alignment film, the solvent, and the liquid crystal compound are the same as those described above for the optical film of the present invention.

[Mixed Layer•Alignment Film-Forming Step]

The mixed layer. alignment film-forming step is not particularly limited as long as the alignment film is formed by using a coating solution which contains one kind of solvent or two or more kinds of solvents and in which the solvent has an average SP value of 25 to 55. In this step, for example, the alignment film can be formed by coating the transparent support with a coating solution for an alignment film that contains the aforementioned solvent, the polymer material for an alignment film, and the like and then drying the coating solution.

In the present invention, because the coating properties become excellent, the concentration of solid contents in the coating solution is preferably equal to or less than 60% by mass, and more preferably 30% by mass to 55% by mass.

<Optically Aanisotropic Layer-Forming Step>

In the optically anisotropic layer-forming step, for example, a method for fixing a liquid crystal compound in the alignment state thereof is used. Examples of the method for fixing the liquid crystal compound preferably include a method for fixing a liquid crystal compound having a polymerizable group as the aforementioned liquid crystal compound by means of polymerization. Herein, the optically anisotropic layer may have a single-layer structure or a laminated structure.

[Polarizing Plate]

Hereinafter, various members used in the polarizing plate of the present invention will be specifically described.

The polarizing plate of the present invention has the aforementioned optical film of the present invention and a polarizer.

[Polarizer]

As the polarizer, a general polarizer can be used. Examples of the polarizer which can be used in the present invention include a polarizer composed of a polyvinyl alcohol film dyed with iodine or dichromatic pigment and the like.

[Pressure-Sensitive Adhesive Layer]

A pressure-sensitive adhesive layer may be disposed between the optically anisotropic layer and the polarizer. The pressure-sensitive adhesive layer for laminating the optically anisotropic layer and the polarizer on each other refers to, for example, a substance in which a ratio of a loss modulus G″ to a storage modulus G′ (tan δ=G″/G′) measured by using a dynamic viscoelastometer is 0.001 to 1.5. The substance includes so-called pressure-sensitive adhesives, easily creeping substances, and the like. Examples of the pressure-sensitive adhesive which can be used in the present invention include a polyvinyl alcohol-based pressure-sensitive adhesive, but the present invention is not limited thereto.

[Image Display Device]

Hereinafter, various members used in the image display device of the present invention will be specifically described.

The image display device of the present invention has the aforementioned optical film of the present invention, a polarizer, and a liquid crystal cell or an organic EL display panel.

In the present invention, the layers constituting the image display device may be layered in any order without particular limitation. The image display device may be embodied so as to have the optical film, the polarizer, and the liquid crystal cell in this order from the viewing side, or may be embodied so as to have the polarizer, the optical film, and the liquid crystal cell or the organic EL display panel in this order from the viewing side.

In an embodiment in which the image display device has a polarizer for image display on a viewing side of an image display panel such as a transmission-mode liquid crystal panel, the polarizer may be used as a polarizer in the polarizing plate of the present invention, and the polarizing plate of the present invention may also function as a polarizing plate on the viewing side in the image display device.

[Liquid Crystal Display Device]

As the liquid crystal display device which is an example of the image display device of the present invention, as described above, an embodiment in which the liquid crystal device has the optical film of the present invention, a polarizer, and a liquid crystal cell in this order from the viewing side (FIGS. 3(A) and 3(B)), and an embodiment in which the liquid crystal device has a polarizer, the optical film of the present invention, and a liquid crystal cell in this order from the viewing side (FIGS. 3(C) and 3(D)) are exemplified.

<Liquid Crystal Cell>

The liquid crystal cell used in the image display device (liquid crystal display device) of the present invention preferably adopts a VA mode, an OCB mode, an IPS mode, or a TN mode, but the present invention is not limited thereto.

In the TN-mode liquid crystal cell, when voltage is not applied, rod-like liquid crystal molecules are substantially horizontally aligned in a state of being twisted at an angle of 60° to 120°. The TN-mode liquid crystal cell is most frequently used as a color TFT liquid crystal display device and described in many documents.

In the VA-mode liquid crystal cell, when voltage is not applied, rod-like liquid crystal molecules are substantially vertically aligned. The VA-mode liquid crystal cell includes (1) a VA-mode liquid crystal cell (described in JP1990-176625A (JP-H02-176625A)) in a narrow sense in which rod-like liquid crystal molecules are substantially vertically aligned when voltage is not applied and are substantially horizontally aligned when voltage is applied, (2) a liquid crystal cell (MVA mode) in which the liquid crystal molecules are aligned in the VA mode in multiple domains so as to widen the viewing angle (described in SID97, Digest of tech. Papers (proceeding) 28 (1997), 845), (3) a liquid crystal cell adopting a mode (n-ASM mode) in which rod-like liquid crystal molecules are substantially vertically aligned when voltage is not applied and are twisted and aligned in multiple domains when voltage is applied (described in proceeding of Japanese Liquid Crystal Conference, pp. 58-59 (1998)), and (4) a SURVIVAL-mode liquid crystal cell (presented in LCD International 98). Furthermore, the liquid crystal cell may adopt any of a patterned vertical alignment (PVA) mode, an optical alignment mode, and a polymer-sustained alignment (PSA) mode. Details of these modes are specifically described in JP2006-215326A and JP2008-538819A.

In the IPS-mode liquid crystal cell, rod-like liquid crystal molecules are aligned in a state of being substantially parallel to a substrate, and when an electric field parallel to the plane of the substrate is applied, the liquid crystal molecules planarly respond. In the IPS mode, black display is performed when an electric field is not applied, and absorption axes of a pair of polarizing plates layered on each other are orthogonal to each other. A method for improving a viewing angle by reducing the amount of light leakage at the time of black display in an oblique direction by using an optical compensation sheet is disclosed in JP1998-54982A (JP-H10-54982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

[Organic EL Display Device]

As the organic EL display device which is an example of the image display device of the present invention, as described above, an embodiment is exemplified in which the device has a polarizer, the optical film of the present invention, and an organic EL display panel in this order from the viewing side (FIGS. 4(A) and 4(B)).

The organic EL display panel is a display panel constituted with an organic EL element in which an organic light emitting layer (organic electroluminescence layer) is interposed between electrodes (a negative electrode and a positive electrode).

The constitution of the organic EL display panel is not particularly limited, and a known constitution can be adopted.

### EXAMPLES

Hereinafter, the present invention is more specifically described based on examples. The materials, the amount of the materials used, the ratio of the materials, the treatment content, the treatment procedure, and the like described in the following examples can be appropriately modified as long as the modification does not depart from the gist of the present invention. Therefore, the scope of the present invention is not limited to the following examples.

### Example 1

<Preparation of Optical Film>

(Preparation of Dope)

The components composed as below were put into a mixing tank and stirred while being heated, thereby dissolving the components and preparing a dope.

| Composition of dope | | |
|---|---|---|
| PMMA resin (Dianal BR88, weight average molecular | 100 | parts by mass |
| weight: 1,500,000, manufactured by Mitsubishi Rayon | | |
| Co., Ltd.) | | |
| Compound of reducing moisture permeability (B-7) | 10 | parts by mass |
| Ultraviolet absorber (Tinuvin 328, manufactured by Ciba | 2.4 | parts by mass |
| Specialty Chemicals, Inc.) | | |
| Brittleness improving agent (LA4285, manufactured by | 5.0 | parts by mass |
| KURARAY CO., LTD.) | | |
| Dichloromethane | 534 | parts by mass |
| Methanol | 46 | parts by mass |

B-7 (molecular weight: 247, available from Wako Pure Chemical Industries, Ltd.)

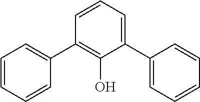 [SMILES: Oc1c(-c2ccccc2)cccc1-c1ccccc1]

(Preparation of Transparent Support)

By using a band-casting device, the prepared dope was uniformly cast in a width of 2,000 mm to an endless band (casting support) made of stainless steel from a casting die.

At a point in time when the amount of the residual solvent in the dope became 15% by mass, a polymer film composed of the dope was peeled off from the casting support. By a tenter, the polymer film was transported without being actively stretched, and dried at a temperature of 120° C. in a drying zone, thereby preparing a transparent support containing an acrylic resin.

(Preparation of Transparent Support with Alignment Film Having Not Yet Undergone Exposure)

By using a #14 wire bar, the prepared transparent support was coated with a coating solution for an alignment film composed as below. The coating solution was dried for 30 seconds at a temperature of 25° C. and then further dried for 100 seconds by being put into an oven at a temperature of 125° C., thereby forming a transparent support with an alignment film having not yet undergone exposure. The film thickness of the alignment film was 0.49 μm.

| Composition 1 of coating solution for alignment film | | |
|---|---|---|
| Polymer (PVA) material (P-1) | 2.50 | parts by mass |
| Photoacid generator (S-1) | 0.20 | parts by mass |
| Radical polymerization initiator (Irgacure 2959, | 0.18 | parts by mass |
| manufactured by Ciba Specialty Chemicals, Inc.) | | |
| Methanol | 43.40 | parts by mass |
| IPA (isopropanol) | 10.32 | parts by mass |
| Pure water | 43.40 | parts by mass |

P-1 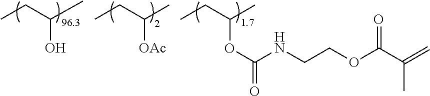
S-1

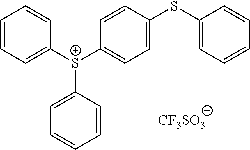

(Ultraviolet Exposure)

In a state in which an angle of 45° was maintained between stripes of a stripe mask and the alignment film, a rubbing treatment was performed on the alignment film by rubbing the alignment film back and forth once in one direction at 900 rpm.

Thereafter, a stripe mask with a transmission portion having a horizontal stripe width of 363 μm and a blocking portion having a horizontal stripe width of 363 μm was disposed on the transparent support with an alignment film having not yet undergone exposure prepared as above. Then, by using an ultraviolet irradiation device (Light Hammer 10, 240 W/cm, manufactured by Fusion UV Systems Inc.) having an illuminance of 500 mW/cm² in a wavelength region of 200 nm to 400 nm as a light source unit, the alignment film was irradiated with ultraviolet rays for 0.06 seconds (30 mJ/cm²) in the air at room temperature, thereby forming a patterned alignment film.

(Formation of Patterned Optically Anisotropic Layer)

Subsequently, by using a #3.2 wire bar, the alignment film was coated with the following coating solution for an optically anisotropic layer. The coating solution was aged by being heated for 1 minute at a film surface temperature of 115° C., then cooled to 90° C., and irradiated with ultraviolet rays for 20 seconds in the air by using an air-cooled metal halide lamp (manufactured by EYE GRAPHICS Co., Ltd.) at 20 mW/cm² so as to fix the alignment state. In this way, a patterned optically anisotropic layer was formed, and an optical film was prepared. In the mask exposure portion (a first phase difference region), a discotic liquid crystal compound was vertically aligned in a state in which the slow axis thereof was parallel to the rubbing direction. In the unexposed portion (a second phase difference region), a discotic liquid crystal compound was vertically aligned in a state in which the slow axis thereof was orthogonal to the rubbing direction. The film thickness of the optically anisotropic layer was 1.16 μm.

| Composition 1 of coating solution for optically anisotropic layer | | |
|---|---|---|
| Discotic liquid crystal E-2 | 80 | parts by mass |
| Discotic liquid crystal E-3 | 20 | parts by mass |
| Alignment agent for alignment film interface (II-1) | 0.9 | parts by mass |
| Alignment agent for alignment film interface (III-1) | 0.08 | parts by mass |
| Alignment agent for air interface (P-2) | 0.2 | parts by mass |
| Alignment agent for air interface (P-3) | 0.6 | parts by mass |
| Photopolymerization initiator (Irgacure 907, manufactured by BASF Japan Ltd.) | 3.0 | parts by mass |
| Polyfunctional monomer (ethylene oxide-modified trimethylolpropane triacrylate (Viscoat 360, manufactured by | 10 | parts by mass |
| OSAKA ORGANIC CHEMICAL INDUSTRY LTD.)) | | |
| Methyl ethyl ketone | 268 | parts by mass |

Discotic liquid crystal compound E-2 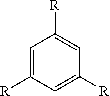 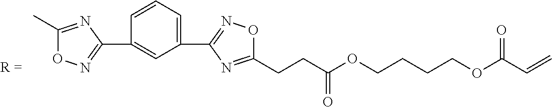 [SMILES: C=CC(=O)OCCCCOC(=O)CCc1nc(-c2cccc(-c3noc(C)n3)c2)no1]
Discotic liquid crystal compound E-3 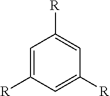 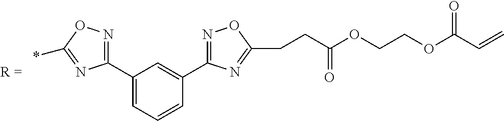 [SMILES: *c1nc(-c2cccc(-c3noc(CCC(=O)OCCOC(=O)C=C)n3)c2)no1]
Alignment agent for alignment film interface (II-1) 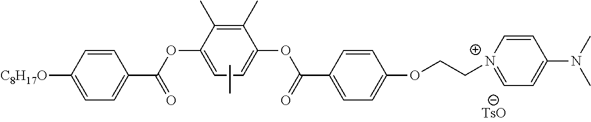
Alignment agent for alignment film interface (III-1) 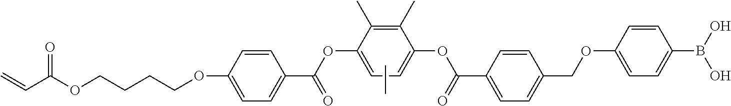
Alignment agent for air interface (P-2) 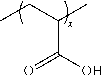 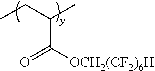
x:y = 2:98
Alignment agent for air interface (P-3) 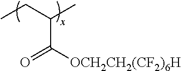 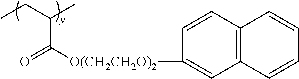
x:y = 32.5:67.5

### Examples 2 to 7 and Comparative Examples 1 to 5

An optical film was prepared by the same method as in Example 1, except that the type and amount of the solvent in the composition of the coating solution for an alignment film were changed as shown in the following Table 1.

### Reference Example 1

An optical film was prepared by the same method as in Example 1, except that the transparent support was changed to a TAC film prepared by the following method.

(1) Preparation of Dope 1 for Core Layer

A dope for a core layer composed as below was prepared.

| Composition of dope | | |
|---|---|---|
| Cellulose acetate (degree of acetylation of 2.86, | 100 | parts by mass |
| number average molecular weight: 72,000) | | |
| Methylene chloride (first solvent) | 320 | parts by mass |
| Methanol (second solvent) | 83 | parts by mass |
| 1-Butanol (third solvent) | 3 | parts by mass |
| Triphenylphosphate | 8.3 | parts by mass |
| Biphenyl diphenyl phosphate | 4.2 | parts by mass |
| Compound 1 | 0.98 | parts by mass |
| Compound 2 | 0.24 | parts by mass |

Compound 1 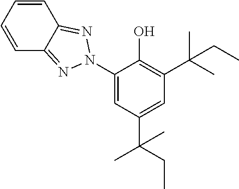 [SMILES: CCC(C)(C)c1cc(-n2nc3ccccc3n2)c(O)c(C(C)(C)CC)c1]
Compound 2

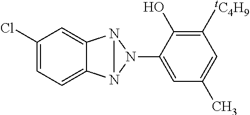

Specifically, the dope for a core layer was prepared by the following method.

The first solvent, the second solvent, and the third solvent were put into a 4,000 L dissolution tank made of stainless steel having a stirring blade and thoroughly stirred. Thereafter, cellulose acetate powder (flake), triphenylphosphate, biphenyl diphenyl phosphate, the compound 1, and the compound 2 were slowly added thereto so as to prepare a solution weighing 2,000 kg in total.

The solution in the dissolution tank was dispersed for 30 seconds, under the condition in which the solution was first dispersed by a dissolver-type eccentric stirring shaft at a rotation speed of 5 m/sec as a stirring and shearing speed and then stirred by an anchor blade in a central shaft at a rotation speed of 1 m/sec (shear stress: 1×10⁴ kgf/m/sec²). After the dispersion ended, the high-speed stirring was stopped, and then the solution was further stirred for 100 minutes with the anchor blade at a rotation speed of 0.5 m/sec.

From the dissolution tank, the solution containing the swollen cellulose acetate powder was transported to a jacketed pipe by using a pump. Thereafter, the solution was heated to 50° C. in the jacketed pipe and then further heated to 90° C. under a pressure of 2 MPa, thereby completely dissolving the solution. The heating time was 15 minutes.

Then, the solution was cooled to 36° C. and passed through a filter medium having a nominal pore size of 8 μm, thereby obtaining a dope.

The dope obtained as above that had not yet been concentrated was caused to flash in a flash device adjusted to be 80° C. at normal pressure, and the evaporating solvent was collected and separated by using a condenser. The concentration of solid contents in the dope having undergone flashing was 21.8% by mass. By using a tank having an anchor blade in the central shaft as a flash tank of the flash device, the dope was defoamed by being stirred at a rotation speed of 0.5 m/sec. The temperature of the dope in the tank was 25° C., and the dope stayed in the tank for 50 minutes on average.

Subsequently, bubbles were removed from the dope by irradiating the dope with weak ultrasonic waves. Then, under a pressure of 1.5 MPa, the dope was first passed through a filter made of sintered fiber metal having a nominal pore size of 10 μm and then passed through a sintered fiber filter having a nominal pore size of 10 μm. The temperature of the filtered dope was adjusted to 36° C., and the dope was stored in a 2,000 L stock tank made of stainless steel. By using a tank having an anchor blade in the central shaft as the stock tank, the dope was consistently stirred at a rotation speed of 0.3 m/sec, thereby obtaining a dope for a core layer.

(2) Preparation of Dope 1-a for Support Layer

A matting agent (silicon dioxide (particle size: 20 nm)), a peeling accelerator (citric acid ethyl ester (mixture of citric acid, monoethyl ester, diethyl ester, and triethyl ester)), and the dope 1 for a core layer were mixed together by using a stationary mixer, thereby preparing a dope 1-a for a support layer. The above components were added in such an amount that the concentration of all the solid contents in the dope became 20.5% by mass, the concentration of the matting agent became 0.05% by mass, and the concentration of the peeling accelerator became 0.03% by mass.

(3) Preparation of Dope 1-b for Air Layer

A matting agent (silicon dioxide (particle size: 20 nm)) was mixed with the dope 1 for a core layer by using a stationary mixer, thereby preparing a dope 1-b for an air layer. The above components were mixed in such an amount that the concentration of all the solid contents in the dope became 20.5% by mass, and the concentration of the matting agent became 0.1% by mass.

(4) Formation of Film by Co-Casting

As a casting die, a device was used which was equipped with a feed block prepared for co-casting and can form a film having a three-layer structure by laminating layers on both surfaces thereof in addition to the main flow. In the following description, a layer formed from the main flow is called a core layer, a layer on the side of the support surface is called a support layer, and a surface on the opposite side thereof is called an air layer. As flow paths for transporting the dope, three flow paths for the core layer, the support layer, and the air layer were used.

From a casting port, the dope for a core layer, the dope 1-a for a support layer, and the dope 1-b for an air layer were co-cast onto a drum cooled to −5° C. At this time, the flow rate of each of the dopes was adjusted such that the thickness ratio of air layer/core layer/support layer became 3/54/3. The dope film cast was dried on the drum by being exposed to dry air at a temperature of 34° C. at a rate of 230 m³/min, and in a state in which the ratio of the residual solvent was 150%, the film was peeled off from the drum. At the time of peeling, the film was stretched 17% in the transport direction (longitudinal direction). Thereafter, in a state in which both ends of the film in the width direction (direction orthogonal to the casting direction) were gripped by a pin tenter (pin tenter described in FIG. 3 in JP1992-1009A (JP-H04-1009A)), the film was transported. The film was then further dried by being transported between rolls of a thermal treatment device, thereby manufacturing a TAC film having a film thickness of about 60 μm.

### Reference Example 2

An optical film was prepared by the same method as in Example 1, except that the transparent support was changed to a PET film prepared by the following method.

(Preparation of PET Film)

As a raw material of a substrate film, 90 parts by mass of polyester resin pellets not containing particles were dried under reduced pressure (1 Torr) for 6 hours at a temperature of 135° C., then supplied to an extruder, and dissolved at a temperature of 285° C. The polymer was filtered through a filter medium (having a nominal pore size of 10 μm, cutting off 95% of particles) made of sintered stainless steel and extruded in the formed of a sheet from the nozzle. Thereafter, by using a casting method applying static electricity, the polymer was wound around a casting drum having a surface temperature of 30° C. and cooled and solidified, thereby preparing an unstretched film.

The unstretched film was guided to a tenter stretcher, and in a state in which the end of the film was gripped, the film was guided to a hot air zone at a temperature of 125° C. and stretched by 4.0 times in the width direction. Then, in a state in which the film was kept stretched in the width direction such that the width was maintained, the film was treated for 30 seconds at a temperature of 225° C. and then further treated so as to be relaxed 3% in the width direction, thereby obtaining a uniaxially aligned PET film having a film thickness of about 50 μm.

### Example 8

An optical film was prepared by the same method as in Example 1, except that the way the procedure for forming the alignment film and the optically anisotropic layer was changed as below.

(Formation of Alignment Film)

By using a #16 wire bar coater, the support was coated with a coating solution for an alignment film composed as below at a rate of 28 mL/m². The coating solution was dried for 60 seconds by hot air at a temperature of 60° C. and then further dried for 150 seconds by hot air at a temperature of 90° C., thereby preparing an alignment film.

| Composition 2 of coating solution for alignment film | | |
|---|---|---|
| Modified polyvinyl alcohol represented by the | 10 | parts by mass |
| following formula | | |
| IPA | 490 | parts by mass |
| Glutaraldehyde (cross-linking agent) | 0.5 | parts by mass |
| Citric acid ester (AS3 manufactured by SANKYO | 0.35 | parts by mass |
| CHEMICAL CO., LTD.) | | |

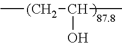

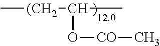

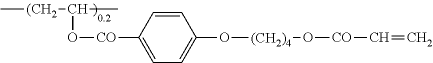

The alignment film was dried for 60 seconds at a temperature of 25° C., 60 seconds by hot air at a temperature of 60° C., and then 150 seconds by hot air at a temperature of 90° C. The thickness of the alignment film having undergone drying was 1.1 μm.

(Rubbing Treatment)

The formed alignment film was transported at a velocity of 20 m/min. Furthermore, in order to make the alignment film rubbed in the longitudinal direction, a rubbing roll (diameter: 300 mm) was set and rotated at 650 rpm, thereby performing a rubbing treatment on the surface of the cellulose acylate film on which the alignment film was disposed.

(Formation of Optically Anisotropic Layer)

Subsequently, by using a #2.8 wire bar, the alignment film was coated with a discotic liquid crystal-containing coating solution composed as below by means of rotating the wire bar at 391 rpm in the same direction as the transport direction of the film, thereby continuously coating the surface of the alignment film transported at a velocity of 20 m/min.

| Composition 2 of coating solution for optically anisotropic layer | | |
|---|---|---|
| Discotic liquid crystal compound shown in the following Structural | 91 | parts by mass |
| formula (C) | | |
| Fluorine-based polymer A having the following structure | 4 | parts by mass |
| Ethylene oxide-modified trimethylolpropane triacrylate (V#360, | 9 | parts by mass |
| manufactured by OSAKA ORGANIC CHEMICAL INDUSTRY LTD.) | | |
| Sensitizer (Kayacure DETX, manufactured by Nippon Kayaku Co., Ltd.) | 1 | part by mass |
| Photopolymerization initiator (Irgacure 907, manufactured by Ciba Geigy, Ltd.) | 3 | parts by mass |
| Methyl ethyl ketone | 212 | parts by mass |

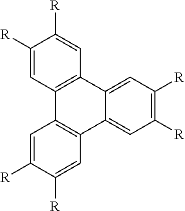

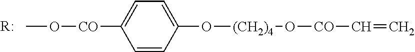

Structural formula (C) 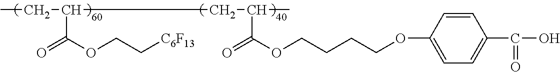
Fluorine-based polymer A

Then, through a step of continuously heating the coating solution to 100° C. from room temperature, the solvent was dried. Thereafter, in a drying zone at a temperature of 130° C., the coating solution was heated for about 90 seconds by wind blowing at a velocity of 2.5 m/sec to the surface of the discotic liquid crystal compound layer, thereby aligning the discotic liquid crystal compound.

Subsequently, in a state in which the film surface temperature was kept at about 130° C., the alignment film was irradiated with ultraviolet rays for 4 seconds by using an ultraviolet irradiation device (ultraviolet lamp: output of 120 W/cm) so as to cause a cross-linking reaction, thereby fixing the alignment of the discotic liquid crystal compound.

### Example 9

An optical film was prepared by the same method as in Example 8, except that the procedure for forming the optically anisotropic layer was changed as below.

(Formation of Optically Anisotropic Layer)

A rubbing treatment was continuously performed on the alignment film. At this time, the longitudinal direction of the long film was parallel to the transport direction, and the rubbing roller was positioned such that the rotational axis thereof was tilted by an angle of 45° C. in a clockwise direction with respect to the longitudinal direction of the film.

By using a #2.7 wire bar, the alignment film formed as described above was continuously coated with a discotic liquid crystal-containing coating solution composed as below. The transport velocity (V) of the film was 36 m/min In order to dry the solvent of the coating solution and to align and age the discotic liquid crystal compound, the coating solution was heated for 90 seconds by hot air at a temperature of 80° C. Then, by performing UV irradiation on the alignment film at a temperature of 80° C., an optically anisotropic layer was formed in which the alignment of the liquid crystal compound was fixed. In this way, an optical film was obtained.

| Composition 3 for coating solution for optically anisotropic layer | | |
|---|---|---|
| The following discotic liquid crystal compound | 100 | parts by mass |
| Photopolymerization initiator (Irgacure 907, manufactured by Ciba Japan K.K.) | 3 | parts by mass |
| Sensitizer (Kayacure DETX, manufactured by Nippon Kayaku, Co., Ltd.) | 1 | part by mass |
| The following pyridinium salt | 1 | part by mass |
| The following fluorine-based polymer (FP1) | 0.4 | parts by mass |
| Methyl ethyl ketone | 252 | parts by mass |

Discotic liquid crystal compound 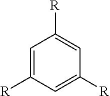 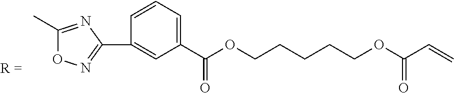 [SMILES: C=CC(=O)OCCCCCOC(=O)c1cccc(-c2noc(C)n2)c1]
Pyridinium salt 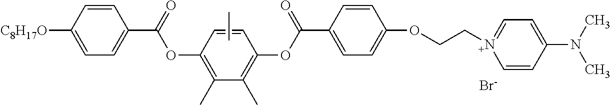
Fluorine-based polymer (FP1) 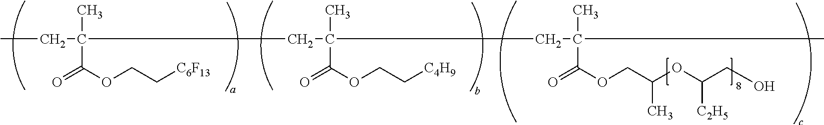
a/b/c = 20/20/60 wt %
Mw = 16,000

### Example 10

An optical film was prepared by the same method as in Example 1, except that the procedure for forming the optically anisotropic layer was changed as below.

(Formation of Optically Anisotropic Layer)

By using a #3.2 wire bar, the surface of the alignment film, which had undergone optical alignment treatment, of the film transported at a velocity of 10 m/min was continuously coated with a coating solution for an optically anisotropic layer composed as below, by means of rotating the wire bar at 391 rpm in the same direction as the transport direction of the film. The coating amount was 4 ml/m². In a state of being transported within a heating zone at a temperature of 80° C., the film was dried for 1 minute at a film surface temperature of 80° C., such that the composition with which the film was coated became in a state of a liquid crystal phase, and the liquid crystals were uniformly aligned. Thereafter, the film was cooled to room temperature.

Finally, the film was wound up in the form of a cylinder, thereby obtaining a roll-like optical film. The slow axes of the first phase difference region and the second phase difference region were orthogonal to each other, and the film thickness was 0.9 μm. From the optical film, only the optically anisotropic layer was peeled off, and the average direction of the molecule symmetry axis of the optically anisotropic layer was measured. As a result, it was found that the molecule symmetry axis tilted at an angle of 45° C. with respect to the longitudinal direction of the optical film.

| Composition 4 of coating solution for optically anisotropic layer | | |
|---|---|---|
| Rod-like liquid crystal (I-27) | 100 | parts by mass |
| Horizontal alignment agent (A) | 0.3 | parts by mass |
| Photopolymerization initiator (Irgacure 907, manufactured by BASF Japan Ltd.) | 3.3 | parts by mass |
| Sensitizer (Kayacure DETX, manufactured by Nippon Kayaku Co., Ltd.) | 1.1 | parts by mass |
| Methyl ethyl ketone | 300 | parts by mass |

Rod-like liquid crystal I-27 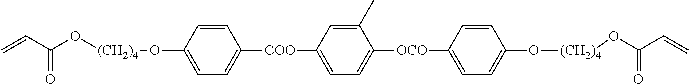
Horizontal alignment agent A

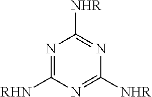

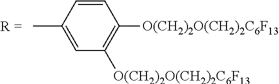

### Example 11

An optical film was prepared by the same method as in Example 1, except that the procedure for forming the alignment film was changed as below.

(Preparation of Transparent Support with Optical Alignment Film)

By using a wire bar, the transparent support prepared in Example 1 was continuously coated with an optical alignment material having the following structure that was dissolved in IPA in a proportion of 1%. By drying the optical alignment material for 60 seconds by hot air at a temperature of 100° C., an optical alignment film was formed. The film thickness of the alignment film was 0.1 μm.

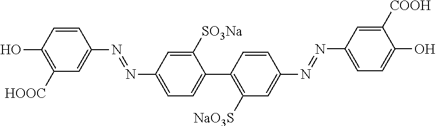

(Optical Alignment Treatment)

The support on which the optical alignment film was formed was transported at a velocity of 10 m/min, and through an exposure slit positioned 10 mm above the substrate, the optical alignment film was irradiated with polarized ultraviolet rays for 0.1 seconds at 1,000 mW/cm², thereby imparting an optical alignment function for the first phase difference region. Herein, the polarization axis of the exposure to polarized light tilted by 45° C. with respect to the transport direction.

Then, by transport rollers arranged in series, the film was continuously transported to a roller (drum) which will become a pedestal for pattern exposure. On the roller which will become the pedestal, through a photomask, which was positioned on the support on which the optical alignment film was formed and had slits formed at a pitch of 200 μm in a direction parallel to the transport direction, and an exposure slit, which was parallel to the photomask and was positioned 10 mm above the substrate, the film was irradiated with polarized ultraviolet rays for 0.4 seconds at 1,000 mW/cm², thereby imparting an optical alignment function for the second phase difference region. The stripe pattern of the photomask was parallel to the transport direction. That is, in the photomask, a transmission portion and a blocking portion were alternately arranged in a direction orthogonal to the transport direction. The polarization axis of the exposure to the polarized light tilted by −45° C. with respect to the transport direction, and the roller which will become the pedestal was cooled with water so as to impart a temperature control function. In this way, the support temperature was controlled at a temperature of equal to or less than 40° C. throughout the exposure step. Furthermore, during the exposure, the support was kept pressed on the roller.

### Example 12

The following antiglare hardcoat layer was formed on the surface of the optical film prepared in Example 1 on which the optically anisotropic layer was formed.

(Antiglare Hardcoat Layer)

The following components were mixed with a solvent mixture of methyl isobutyl ketone (MIBK) and methyl ethyl ketone (MEK) (MIBK:MEK=89:11 (mass ratio)) such that the following composition was obtained. The mixture was filtered through a polypropylene filter having a pore size of 30 μm, thereby preparing a coating solution 1 for an antiglare hardcoat layer. The concentration of solid contents in each coating solution was 40% by mass. Herein, at the time of preparing the coating solution, resin particles and smectite were added in the form of a dispersion which will be described later.

| Coating solution 1 for antiglare hardcoat layer | | |
|---|---|---|
| Smectite (Lucentite STN, manufactured by CO-OP | 1.00% | by mass |
| CHEMICAL CO., LTD.) | | |
| Resin particles (Techpolymer SSX, manufactured by | 8.00% | by mass |
| SEKISUI PLASTICS CO., LTD.) | | |
| Acrylate monomer (NK Ester A9550, maanufactured by | 87.79% | by mass |
| SHIN-NAKAMURA CHEMICAL CO., LTD.) | | |
| Polymerization initiator (Irgacure 907, maanufactured by | 3.00% | by mass |
| BASF Japan Ltd.) | | |
| Leveling agent (P-4) | 0.15% | by mass |
| Dispersant (DISPERBYK-2164, manufactured by BYK- | 0.05% | by mass |
| Chemie Japan K.K.) | | |

Leveling agent (P-4) 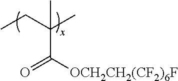 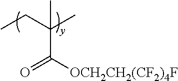 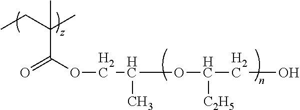
x:y:z = 25:25:50, n = 8

(Preparation of Resin Particle Dispersion)

A dispersion of light-transmitting resin particles was prepared by slowly adding light-transmitting resin particles (Techpolymer SSX, manufactured by SEKISUI PLASTICS CO., LTD.) to an MIBK solution, which was being stirred, until the concentration of solid contents in the dispersion became 30% by mass and stirring the resultant for 30 minutes.

(Preparation of Smectite Dispersion)

A smectite dispersion was prepared by slowly adding smectite (Lucentite STN, manufactured by CO-OP CHEMICAL CO., LTD.) to the entirety of MEK, which was finally used in the coating solution 1 for an antiglare hardcoat layer, with stirring and further stirring the resultant for 30 minutes.

(Formation of Antiglare Layer 1 by Coating)

The support on which the optically anisotropic layer was formed was wound off in the form of a roll and coated with the coating solution 1 for an antiglare hardcoat layer such that the film thickness became 4 μm, thereby forming an antiglare layer by coating.

Specifically, by a die coating method using a slot die described in Example 1 of JP2006-122889A, the support was coated with each coating solution under a condition of a transport velocity of 30 m/min, and the coating solution was dried for 150 seconds at a temperature of 80° C. Thereafter, in an atmosphere purged with nitrogen and having an oxygen concentration of about 0.1%, by using an air-cooled metal halide lamp (manufactured by EYE GRAPHICS Co., Ltd.) at 160 W/cm, the coating layer was irradiated with ultraviolet rays at an illuminance of 400 mW/cm² and an irradiation amount of 180 mJ/cm² such that the coating layer was cured, thereby forming an antiglare hardcoat layer.

### Example 13

An optical film was prepared by the same method as in Example 1, except that the procedure for forming the optically anisotropic layer was changed as below.

(Formation of Optically Anisotropic Layer A)

On the surface of the alignment film, a rubbing treatment was continuously performed in a direction tilting to the left by an angle of 60° with respect to the longitudinal direction of the transparent support. By using a bar coater, the surface having undergone the rubbing treatment was coated with the following coating solution for an optically anisotropic layer. Thereafter, the coating solution was aged by being heated for 90 seconds at a film surface temperature of 115° C. and then cooled to 80° C. Then, in the air, by using an air-cooled metal halide lamp (manufactured by EYE GRAPHICS Co., Ltd.) at 20 mW/cm², the coating layer was irradiated with ultraviolet rays at an irradiation amount of 200 mJ/cm² such that the alignment state was fixed, thereby forming an optically anisotropic layer A. In the formed optically anisotropic layer A, discotic liquid crystals were vertically aligned in a state in which the slow axis direction was orthogonal to the rubbing direction. The values of retardation of the optically anisotropic layer A at wavelengths of 450 nm, 550 nm, and 650 nm were as follows. Herein, the thickness of the optically anisotropic layer was 2.5 μm.

ReA(450): 273 nm

ReA(550): 250 nm

ReA(650): 240 nm

ReA(450)/ReA(650): 1.14

| Composition of coating solution for optically anisotropic layer (coating solution for forming optically anisotropic | | |
|---|---|---|
| layer A) | | |
| Discotic liquid crystal E-1 | 80 | parts by mass |
| Discotic liquid crystal 2 | 20 | parts by mass |
| Alignment agent 1 for alignment film interface | 0.55 | parts by mass |
| Alignment agent 2 for alignment film interface | 0.05 | parts by mass |
| Fluorine-containing compound | 0.1 | parts by mass |
| Modified trimethylolpropane triacrylate | 10 | parts by mass |
| Photopolymerization initiator (Irgacure 907, manufactured by Ciba Specialty Chemicals, Inc.) | 3.0 | parts by mass |
| Interlayer alignment agent | 0.6 | parts by mass |
| Methyl ethyl ketone | 180 | parts by mass |
| Cyclohexanone | 20 | parts by mass |

Discotic liquid crystal E-1 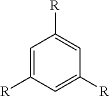 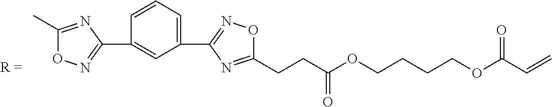 [SMILES: C=CC(=O)OCCCCOC(=O)CCc1nc(-c2cccc(-c3noc(C)n3)c2)no1]
Discotic liquid crystal 2 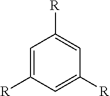 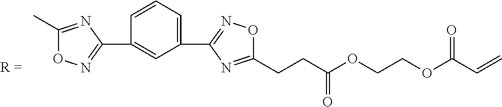 [SMILES: C=CC(=O)OCCOC(=O)CCc1nc(-c2cccc(-c3noc(C)n3)c2)no1]
Alignment agent 1 for alignment film interface 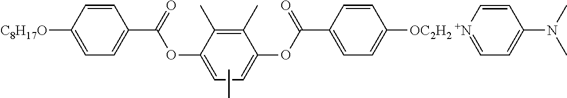 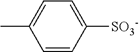
Alignment agent 2 for alignment film interface 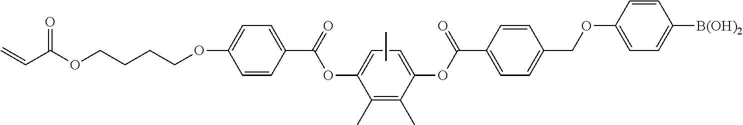
Fluorine-containing compound 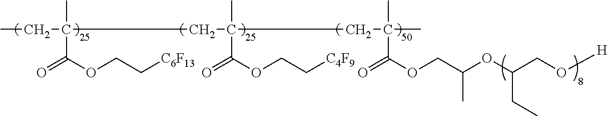
Modified trimethylolpropane triacrylate 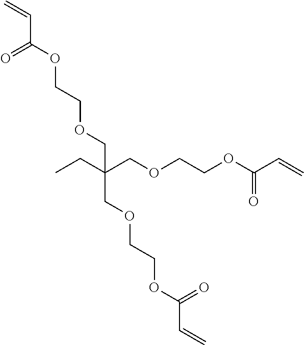 [SMILES: C=CC(=O)OCCOCC(CC)(COCCOC(=O)C=C)COCCOC(=O)C=C]
Interlayer alignment agent

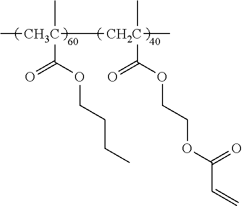

(Formation of Optically Anisotropic Layer B)

A rubbing treatment was continuously performed on the surface of the optically anisotropic layer A, in a direction orthogonal to the slow axis of the optically anisotropic layer A. By using a bar coater, the surface having undergone the rubbing treatment was coated with the following coating solution for an optically anisotropic layer. Thereafter, the coating film was aged by being heated for 60 seconds at a film surface temperature of 60° C. and irradiated with ultraviolet rays in the air by using an air-cooled metal halide lamp (manufactured by EYE GRAPHICS Co., Ltd.) at 20 mW/cm², thereby fixing the alignment state and forming an optically anisotropic layer B. In the formed optically anisotropic layer B, rod-like liquid crystals were horizontally aligned in a state in which the slow axis direction thereof was parallel to the rubbing direction. The values of retardation of the optically anisotropic layer B at wavelengths of 450 nm, 550 nm, and 650 nm were as follows. Herein, the thickness of the optically anisotropic layer B was 1.0 μm.

ReB(450): 141 nm

ReB(550): 125 nm

ReB(650): 120 nm

ReB(450)/ReB(650): 1.18

ReA(550) of the optically anisotropic layer A and ReB(550) of the optically anisotropic layer B had a relationship of ReA(550)>ReB(550).

| Composition of coating solution for optically anisotropic layer (coating solution for forming optically anisotropic layer B) | | |
|---|---|---|
| Rod-like liquid crystal compound 1 | 90 | parts by mass |
| Rod-like liquid crystal compound 2 | 10 | parts by mass |
| Photopolymerization initiator (Irgacure 907, manufactured by Ciba Specialty Chemicals, Inc.) | 3.0 | parts by mass |
| Sensitizer (Kayacure DETX, manufactured by Nippon Kayaku Co. ,Ltd.) | 1.0 | part by mass |
| Fluorine-containing compound | 0.5 | parts by mass |
| Methyl ethyl ketone | 400 | parts by mass |

Rod-like liquid crystal compound 1 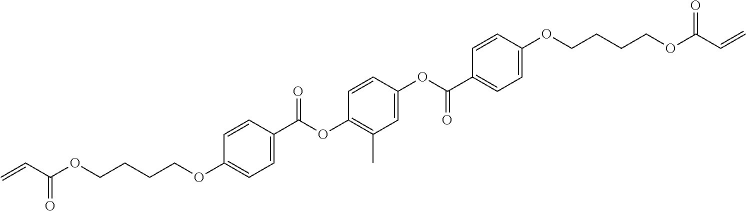 [SMILES: C=CC(=O)OCCCCOc1ccc(C(=O)Oc2ccc(OC(=O)c3ccc(OCCCCOC(=O)C=C)cc3)c(C)c2)cc1]
Rod-like liquid crystal compound 2 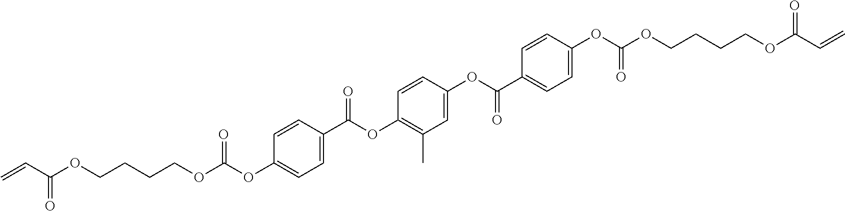 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]
Fluorine-containing compound

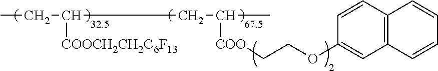

By the following method, each of the prepared optical films were evaluated in terms of the adhesiveness, presence of wrinkles (deformation), unevenness of in-plane retardation, and linearity. The results are shown in the following Table 1.

In the following Table 1, regarding the form of the optically anisotropic layer, the form of the optically anisotropic layer formed by the method of Example 1 is denoted by “A”, the form of the optically anisotropic layer formed by the method of Example 8 is denoted by “B”, the form of the optically anisotropic layer formed by the method of Example 9 is denoted by “C”, and the form of the optically anisotropic layer formed by the method of Example 13 is denoted by “D”.

Furthermore, in the following Table 1, regarding the liquid crystal material of the optically anisotropic layer, a case in which a discotic liquid crystal compound is used is denoted by “DLC: Discotic Liquid Crystal”.

<Adhesiveness>

The adhesiveness was evaluated by the cross-cut method described in JIS K5600-5-6:1999.

Specifically, the surface (on the side of the optically anisotropic layer) of the prepared optical film was patterned with 100 grid squares at intervals of 1 mm, and an NT tape manufactured by NITTO DENKO CORPORATION was bonded thereto. Subsequently, a weight weighing 100 g was rubbed back and forth 10 times against the tape such that the tape adhered to the film, and after 10 minutes, the tape was peeled off. This step was repeated 5 times. Then, the number of squares, in which the film remained without being peeled off, among the 100 squares was counted and evaluated based on the following criteria.

A: The number of squares where peeling occurred was equal to or less than 10, which showed the film had excellent adhesiveness.

B: Peeling occurred in 11 to 99 squares, which showed the film had poor adhesiveness.

C: Peeling occurred in 100 squares, which showed the film had extremely poor adhesiveness.

<Presence of Wrinkle>

The prepared optical film was cut in a length of 1 mm, and in a state in which tension was not applied, the film was expanded and visually observed to see whether it was deformed to have irregularity in the longitudinal direction. In this way, the presence of wrinkles was checked and evaluated based on the following criteria.

A: Marked irregularity was not visually observed.

B: A single marked irregularity was observed in the plane of the film.

C: Two or more marked irregularities were observed in the plane of the film.

<Unevenness of In-Plane Retardation>

In order to evaluate the unevenness of in-plane retardation, by using KOBRA-21ADH (manufactured by Oji Scientific Instruments), Re in each of 100 random points in the prepared optical film was measured, and the difference between an absolute maximum Re and an absolute minimum Re was calculated for each of the films.

A: The difference between the maximum Re and the minimum Re was equal to or less than 5 nm

B: The difference between the maximum Re and the minimum Re was greater than 5 nm and equal to or less than 8 nm

C: The difference between the maximum Re and the minimum Re was greater than 8 nm and equal to or less than 10 nm

<3D Display Unevenness>

By the following method, the optical film having an optically anisotropic layer of the form A was evaluated in terms of 3D display unevenness.

The 3D display unevenness was assessed by forcible evaluation by using an image in which the 3D display unevenness was easily visually observed.

Specifically, the liquid crystal display device was caused to display a stripe image composed of black stripes and white stripes alternately layered on each other. Then, wearing a pair of 3D eyeglasses, an observer looked straight at the liquid crystal display device while blocking one of the eyeglasses through which the white stripes were visually observed. The 3D display unevenness was evaluated based on the following criteria. In the evaluation, a black display portion in the display screen means that there is no crosstalk or small crosstalk. Furthermore, a portion in which brightness leakage is visually observed and a white display portion mean that there is crosstalk.

(Evaluation Criteria)

A: In the forcible evaluation, black display was performed within the whole display screen, and crosstalk was not visually observed at all. Alternatively, slight brightness leakage was visually observed, yet it was at an allowable level. In the evaluation using a 3D video source, crosstalk was not visually observed.

B: In the forcible evaluation, brightness leakage was visually observed. However, in the evaluation using a 3D video source, crosstalk was practically not observed.

C: In the forcible evaluation, brightness leakage was visually observed. Furthermore, in the evaluation using a 3D video source, crosstalk was visually observed.

<Linearity>

By the following method, the optical film having an optically anisotropic layer of the form A was evaluated in terms of linearity.

The maximum amount of deviation of the stripe-like pattern of the patterned optically anisotropic layer of the optical film from the stripe line was evaluated.

Specifically, the optical film was cut in such a size that the longitudinal direction of the optical film was taken as a long side and the cut film could be bonded to a 42 inch wide liquid crystal. Then, the maximum amount of deviation of the stripe from a straight line was determined. For practical use, A, B, and C are preferable, A and B are more preferable, and A is most preferable.

A: The maximum amount of deviation was equal to or less than 10 μm.

B: The maximum amount of deviation was greater than 10 μm and equal to or less than 20 μm.

C: The maximum amount of deviation was greater than 20 μm and equal to or less than 30 μm.

D: The maximum amount of deviation was greater than 30 μm and equal to or less than 60 μm.

E: The maximum amount of deviation was greater than 60 μm.

<Pattern Characteristics (Boundary Line Width)>

By the following method, the optical film having an optically anisotropic layer of the form A was evaluated in terms of pattern characteristics.

The patterned optically anisotropic layer of the optical film was inserted between polarizing plates, such that the slow axis of one of the first phase difference region and the second phase difference region became parallel to the polarization axis of one of the two sheets of polarizing plates combined to be orthogonal to each other. Furthermore, a sensitive color plate having a phase difference of 530 nm was placed on the optically anisotropic layer, such that an angle of 45° was formed between the slow axis of the sensitive color plate and the polarization axis of the polarizing plate. The width of the boundary region of the stripe patterns observed at this time was defined as a boundary line width. The smaller the boundary line width, the higher the in-plane uniformity, and the optical film can be evaluated to result in excellent 3D image quality.

TABLE 1

| | | Optically | | Alignment film | | | | | |
|---|---|---|---|---|---|---|---|---|---|
| | | anisotropic | | | Coating solution | | | | |
| | | layer | | | | | Average | Concentration | |
| | | | Liquid | | Solvent | | SP | of solid | |
| | Transparent | | crystal | | (% by mass with respect to | | value of | contents | Hardcoat |
| | support | Form | material | Material | all solvents) | | solvent | (% by mass) | layer |
| Example 1 | Acryl | A | DLC | PVA | Water (50) | Methanol | 55 | 2.88 | Absent |
| | | | | | | (50) | | | |
| Example 2 | Acryl | A | DLC | PVA | Water (50) | Ethanol | 52 | 2.88 | Absent |
| | | | | | | (50) | | | |
| Example 3 | Acryl | A | DLC | PVA | Water (25) | Ethanol | 41 | 13.20 | Absent |
| | | | | | | (75) | | | |
| Example 4 | Acryl | A | DLC | PVA | Ethanol (100) | | 31 | 13.20 | Absent |
| Example 5 | Acryl | A | DLC | PVA | IPA (100) | | 27 | 13.20 | Absent |
| Example 6 | Acryl | A | DLC | PVA | n-BuOH (100) | | 26 | 13.20 | Absent |
| Example 7 | Acryl | A | DLC | PVA | i-BuOH (100) | | 25 | 13.20 | Absent |
| Example 8 | Acryl | B | DLC | PVA | IPA (100) | | 27 | 2.17 | Absent |
| Example 9 | Acryl | C | DLC | PVA | IPA (100) | | 27 | 2.17 | Absent |
| Example 10 | Acryl | A | Rod-like | PVA | IPA (100) | | 27 | 2.88 | Absent |
| | | | liquid | | | | | | |
| | | | crystal | | | | | | |
| Example 11 | Acryl | A | DLC | Optical | IPA (100) | | 27 | 1.00 | Absent |
| | | | | alignment | | | | | |
| | | | | film | | | | | |
| Example 12 | Acryl | A | DLC | PVA | IPA (100) | | 27 | 2.88 | Present |
| Example 13 | Acryl | D | DLC | PVA | Water (50) | Methanol | 55 | 2.88 | Absent |
| | | | | | | (50) | | | |
| Comparative | Acryl | A | DLC | PVA | Water (55) | Methanol | 56 | 2.88 | Absent |
| example 1 | | | | | | (45) | | | |
| Comparative | Acryl | A | DLC | PVA | Water (75) | Methanol | 63 | 2.88 | Absent |
| example 2 | | | | | | (25) | | | |
| Comparative | Acryl | A | DLC | PVA | Water (100) | | 72 | 13.20 | Absent |
| example 3 | | | | | | | | | |
| Comparative | Acryl | A | DLC | PVA | MEK (52) | IPA (48) | 24 | 2.88 | Absent |
| example 4 | | | | | | | | | |
| Comparative | Acryl | A | DLC | PVA | MEK (100) | | 22 | 2.88 | Absent |
| example 5 | | | | | | | | | |
| Reference | TAC | A | DLC | PVA | MEK (100) | | 22 | 2.88 | Absent |
| example 1 | | | | | | | | | |
| Reference | PET | A | DLC | PVA | MEK (100) | | 22 | 2.88 | Absent |
| example 2 | | | | | | | | | |

| | | Evaluation | | | | | |
|---|---|---|---|---|---|---|---|
| | | | | | | | Pattern |
| | Thickness | | | | | | characteristics |
| | of mixing | Adhesiveness | | Unevenness | | | Boundary line |
| | layer | Cross-cut | | of in-plane | 3D display | | width |
| | (nm) | (n/100) | Wrinkle | Re | unevenness | Linearity | (μm) |
| Example 1 | 51 | A (92/100) | A | A | A | A | 5~6 |
| Example 2 | 79 | A (97/100) | A | A | A | A | 5~6 |
| Example 3 | 102 | A (99/100) | A | A | A | A | 5~6 |
| Example 4 | 159 | A (100/100) | A | A | A | B | 5~6 |
| Example 5 | 181 | A (100/100) | A | A | A | B | 5~6 |
| Example 6 | 188 | A (100/100) | A | A | A | B | 5~6 |
| Example 7 | 196 | A (100/100) | A | A | A | B | 5~6 |
| Example 8 | 181 | A (100/100) | A | A | — | — | — |
| Example 9 | 181 | A (100/100) | A | A | — | — | — |
| Example 10 | 51 | A (100/100) | A | A | A | A | 5~6 |
| Example 11 | 181 | A (100/100) | A | A | A | A | 10~16 |
| Example 12 | 51 | A (100/100) | A | A | A | A | 5~6 |
| Example 13 | 51 | A (92/100) | A | A | — | — | — |
| Comparative | 46 | B (48/100) | A | A | A | A | 5~6 |
| example 1 | | | | | | | |
| Comparative | 31 | C (0/100) | A | A | A | A | 5~6 |
| example 2 | | | | | | | |
| Comparative | 22 | C (0/100) | A | A | A | A | 5~6 |
| example 3 | | | | | | | |
| Comparative | 231 | A (100/100) | B | B | A | C | 5~6 |
| example 4 | | | | | | | |
| Comparative | 310 | A (100/100) | C | C | A | E | 5~6 |
| example 5 | | | | | | | |
| Reference | 392 | A (100/100) | A | A | B | E | 5~6 |
| example 1 | | | | | | | |
| Reference | 11 | C (0/100) | A | A | A | E | 5~6 |
| example 2 | | | | | | | |

From Table 1, it was understood that when the average SP value of the solvent contained in the coating solution for forming an alignment film is greater than 55, the thickness of the mixed layer between the transparent support and the alignment film becomes less than 50 nm, and accordingly, the interfacial adhesion between the transparent support and the alignment film is weakened, and the alignment film is easily peeled off (Comparative examples 1 to 3).

Furthermore, it was understood that when the average SP value of the solvent contained in the coating solution for forming an alignment film is less than 25, the thickness of the mixed layer between the transparent support and the alignment film becomes greater than 200 nm, and accordingly, the transparent support contracts when the coating solution was dried, and thus wrinkles easily occur (Comparative examples 4 and 5).

It was also understood that regarding the embodiment in which the average SP value of the solvent contained in the coating solution for forming an alignment film is beyond the range of 25 to 55, the examples in which the form of the optically anisotropic layer was changed to the forms B to D show the same tendency as the Comparative examples 1 to 5.

In addition, it was understood that even when the average SP value of the solvent contained in the coating solution for forming an alignment film is less than 25, if a TAC film or a PET film is used as a transparent support, wrinkles do not occur, but the linearity or adhesiveness deteriorates (Reference examples 1 and 2).

In contrast, it was understood that the optical film, which has an alignment film formed by using the coating solution containing a solvent having an average SP value of 25 to 55 and has a mixed layer having a thickness of 50 nm to 200 nm formed between the transparent support and the alignment film, does not have wrinkles and is excellent in the adhesiveness between the support and the alignment film (Examples 1 to 13).

Particularly, from the comparison between Examples 1 to 7, it was understood that if the average SP value of the solvent of the coating solution for forming an alignment film is 25 to 40, the adhesiveness between the support and the alignment film is further improved.

In addition, from the comparison between Example 5 and Example 11, it was understood that when the alignment film contains a polyvinyl alcohol derivative, the pattern characteristics are improved.

### EXPLANATION OF REFERENCES

10: optical film

12: optically anisotropic layer

12a: first phase difference region

a: slow axis of first phase difference region

12b: second phase difference region

b: slow axis of second phase difference region

14: alignment film

15: mixed layer

16: transparent support

18: hardcoat layer

20: polarizing plate

22: polarizer

23: absorption axis of polarizer

24: polarizer protective film

30: liquid crystal display device

32: liquid crystal cell

34: polarizer

36, 38: polarizer protective film

40: organic EL display device

42: organic EL display panel

What is claimed is:

1. An optical film comprising;
a transparent support;
an alignment film; and
an optically anisotropic layer in this order,
wherein the transparent support contains an acrylic resin, and
a mixed layer, which has a thickness of 50 nm to 200 nm and in which a material constituting the transparent support is mixed with a material constituting the alignment film, is between the transparent support and the alignment film.

2. The optical film according to claim 1,
wherein the alignment film contains a polyvinyl alcohol derivative.

3. The optical film according to claim 1,
wherein in-plane retardation of the optically anisotropic layer is 40 nm to 240 nm at a wavelength of 550 nm.

4. The optical film according to claim 2,
wherein in-plane retardation of the optically anisotropic layer is 40 nm to 240 nm at a wavelength of 550 nm.

5. The optical film according to claim 1,
wherein the optically anisotropic layer is a patterned optically anisotropic layer having two or more phase difference regions which differ from each other in terms of at least one of the direction of in-plane slow axis and the value of in-plane retardation.

6. The optical film according to claim 2,
wherein the optically anisotropic layer is a patterned optically anisotropic layer having two or more phase difference regions which differ from each other in terms of at least one of the direction of in-plane slow axis and the value of in-plane retardation.

7. The optical film according to claim 1, further comprising a hardcoat layer.

8. The optical film according to claim 2, farther comprising a hardcoat layer.

9. A polarizing plate comprising:
the optical film according to claim 1; and
a polarizer.

10. A polarizing plate comprising:
the optical film according to claim 2; and
a polarizer.

11. An image display device comprising:
the optical film according to claim 1;
a polarizer; and
a liquid crystal cell or an organic EL display panel.

12. An image display device comprising:
the optical film according to claim 2;
a polarizer; and
a liquid crystal cell or an organic EL display panel.

13. The image display device according to claim 11, comprising:
the optical film;
the polarizer; and
the liquid crystal cell in this order from a viewing side.

14. The image display device according to claim 12, comprising:
the optical film;
the polarizer; and
the liquid crystal cell in this order from a viewing side.

15. The image display device according to claim 11, comprising:
the polarizer;
the optical film;
and the liquid crystal cell in this order from a viewing side.

16. The image display device according to claim 12, comprising:
the polarizer;
the optical film;
and the liquid crystal cell in this order from a viewing side.

17. The image display device according to claim 11, comprising:
the polarizer;
the optical film; and
the organic EL display panel in this order from a viewing side.

18. The image display device according to claim 12, comprising:
the polarizer;
the optical film; and
the organic EL display panel in this order from a viewing side.

19. An optical-film manufacturing method for preparing the optical film according to claim 1, comprising:
a mixed layer-alignment film-forming step of forming an alignment film on a transparent support containing acrylic resin by using a coating solution, which contains one kind of solvent or two or more kinds of solvents and in which the solvent has an average SP value of 25 to 55, and forming a mixed layer, which has a thickness of 50 nm to 200 nm and in which a material constituting the transparent support is mixed with a material constituting the alignment film, between the transparent support and the alignment film; and
an optically anisotropic layer-forming step of forming an optically anisotropic layer on the alignment film by using a composition for forming an optically anisotropic layer containing a liquid crystal compound so as to prepare an optical film.

20. The optical-film manufacturing method according to claim 19,
wherein the average SP value of the solvent is 25 to 40.

21. The optical-film manufacturing method according to claim 19,
wherein the concentration of solid contents in the coating solution is equal to or less than 60% by mass.

22. The optical-film manufacturing method according to claim 20,
wherein the concentration of solid contents in the coating solution is equal to or less than 60% by mass.
